(19) United States
(12) Patent Application Publication
(10) Pub. No.: US 2006/0163638 A1
(43) Pub. Date: Jul. 27, 2006

(54) Semiconductor device and method for fabricating the same

(76) Inventor: Satoru Ito, Niigata (JP)

Correspondence Address: MCDERMOTT WILL & EMERY LLP, 600 13TH STREET, N.W., WASHINGTON, DC, 20005-3096, US

(21) Appl. No.: 11/189,916

(22) Filed: Jul. 27, 2005

(30) Foreign Application Priority Data
Jan. 24, 2005 (JP) 2005-015579

(51) Int. Cl. H01L 29/00; H01L 21/8242; H01L 27/108; H01L 21/44

(52) U.S. Cl. 257/306; 257/532; 438/396; 438/253

(57) ABSTRACT

A semiconductor device includes a first insulating film formed on a semiconductor substrate; a second insulating film formed on the first insulating film and having a recess corresponding to a capacitor region; a lower electrode formed in the recess; a capacitor dielectric film formed on the lower electrode; and an upper electrode formed on the capacitor dielectric film. The semiconductor device further includes a conductive portion formed in the first insulating film and the second insulating film for electrically connecting the semiconductor substrate to the upper electrode.

### CROSS-REFERENCE TO RELATED APPLICATIONS

This application claims priority under 35 U.S.C. §119 on Patent Application No. 2005-015579 filed in Japan on Jan. 25, 2005, the entire contents of which are hereby incorporated by reference.

### BACKGROUND OF THE INVENTION

The present invention relates to a semiconductor device and a method for fabricating the same, and more particularly, it relates to a semiconductor device including a stack type capacitor and a method for fabricating the same.

Recently, there are demands that a semiconductor device such as a DRAM (dynamic random access memory) should have a smaller memory cell area for attaining refinement and a high degree of integration and have larger capacitance per unit area of a memory cell capacitor. In order to meet the demands, a variety of capacitor structures have been proposed. In particular, in a stack type capacitor, it is easy to increase an opposing area between electrodes of the capacitor owing to its structure, and therefore, even when elements are refined as a result of an increased degree of integration of the semiconductor device, sufficient capacity of the capacitor can be attained. Accordingly, a stack type capacitor is more frequently used in accordance with the increase of the degree of integration of a semiconductor device.

Now, a method for fabricating a conventional semiconductor device will be described with reference to drawings.

FIGS. 20A through 20C, 21A through 21C, 22A through 22C, 23A, 23B, 24A and 24B are cross-sectional views for showing procedures in the method for fabricating a semiconductor device including a conventional stack type capacitor.

First, as shown in FIG. 20A, a shallow trench isolation region 1 is formed in a general silicon substrate 50. Then, after successively depositing a gate insulating film (not shown) and a first polysilicon film on the silicon substrate 50, the first polysilicon film is patterned by lithography and etching, thereby forming a gate electrode 2. Next, an n-type impurity such as phosphorous (P) is implanted into the silicon substrate 50 by ion implantation by using the gate electrode 2 as a mask, thereby forming an LDD (lightly doped drain) region 4. Thereafter, a sidewall 3 of an insulating film is formed on the side face of the gate electrode 2, and a first interlayer insulating film 5 is formed on the silicon substrate 50 including the gate electrode 2, and then, the surface of the first interlayer insulating film 5 is planarized.

Next, as shown in FIG. 20B, a plurality of contact holes reaching the LDD region 4 are formed in the first interlayer insulating film 5, and a plug 6A to be connected to a capacitor lower electrode or a plug 6B to be connected to an interconnect (bit line) is formed within each of the contact holes.

Subsequently, as shown in FIG. 20C, a silicon nitride film 7 and a second interlayer insulating film 8 are successively deposited on the first interlayer insulating film 5 including the plugs 6A and 6B. Thereafter, the second interlayer insulating film 8 and the silicon nitride film 7 are etched, so as to form a recess 9 corresponding to a capacitor region. At this point, the top face of the plug 6A is exposed on the bottom of the recess 9.

Then, as shown in FIG. 21A, a second polysilicon film 10 doped with an n-type impurity such as phosphorus (P) is deposited on the second interlayer insulating film 8 including the recess 9. Next, an amorphous silicon film 11 is deposited on the second polysilicon film 10.

Thereafter, as shown in FIG. 21B, the silicon substrate 50 is annealed with monosilane (SiH₄) supplied onto the surface of the amorphous silicon film 11 in a reduced pressure atmosphere, thereby polycrystallizing the amorphous silicon film 11 and growing silicon grains thereon. Thus, an HSG (hemi spherical grained) film 12 is formed on the second polysilicon film 10. Furthermore, the silicon substrate 50 is annealed at a temperature of, for example, 700° C. for approximately 6 minutes in a gas atmosphere including phosphine (PH₃), thereby doping the HSG film 12 with P (phosphorus). The P-doped HSG film 12 thus obtained is used as a lower electrode of a capacitor.

Next, as shown in FIG. 21C, after applying a resist on the HSG film 12, the resist is wholly exposed and developed, thereby allowing a resist film 13 to selectively remain merely within the recess 9 corresponding to the capacitor region.

Then, as shown in FIG. 22A, the HSG film 12 and the second polysilicon film 10 are subjected to anisotropic etching by dry etching with the resist film 13 used as a mask, and then, the resist film 13 is removed. Thus, the HSG film 12 and the second polysilicon film 10 corresponding to the lower electrode are allowed to remain within the recess 9 alone. At this point, the second polysilicon film 10 remaining within the recess 9 is connected to the plug 6A.

Next, as shown in FIG. 22B, after depositing a tantalum oxide film 14 over the whole substrate, the tantalum oxide film 14 is annealed at a temperature of, for example, 800° C. for approximately 60 seconds in an oxygen atmosphere, thereby polycrystallizing the tantalum oxide film 14. Subsequently, a first titanium nitride film 15 is deposited on the tantalum oxide film 14 by CVD (chemical vapor deposition) using titanium chloride (TiCl₄) and ammonia (NH₃) as material gases.

Then, as shown in FIG. 22C, the tantalum oxide film 14 and the first titanium nitride film 15 are patterned, thereby forming a capacitor dielectric film and an upper electrode on the lower electrode (namely, the HSG film 12 and the second polysilicon film 10). Thus, the capacitor is completed. It is noted that the first titanium nitride film 15 corresponding to the upper electrode extends, for plate contact, over the second interlayer insulating film 8 provided in the vicinity of the recess 9 corresponding to the capacitor region.

Thereafter, a third interlayer insulating film 16 is deposited by plasma CVD on the second interlayer insulating film 8 including the first titanium nitride film 15 corresponding to the upper electrode, and the surface of the third interlayer insulating film 16 is planarized.

Next, as shown in FIG. 23A, the third interlayer insulating film 16, the second interlayer insulating film 8 and the silicon nitride film 7 are etched, thereby forming a bit line contact hole 17 reaching the plug 6B and a plate contact hole 18 reaching the first titanium nitride film 15.

Then, as shown in FIG. 23B, a second titanium nitride film 19 working as an adhesion layer is deposited by the CVD on the third interlayer insulating film 16 and within the bit line contact hole 17 and the plate contact hole 18.

Subsequently, as shown in FIG. 24A, a tungsten film 20 is deposited by the CVD on the second titanium nitride film 19 so as to completely fill the bit line contact hole 17 and the plate contact hole 18.

Ultimately, as shown in FIG. 24B, portions of the second titanium nitride film 19 and the tungsten film 20 disposed outside the bit line contact hole 17 and the plate contact hole 18, namely, unnecessary portions of the second titanium nitride film 19 and the tungsten film 20 disposed on the third interlayer insulating film 16, are removed by polishing. Thus, a bit line contact 21 made of the second titanium nitride film 19 and the tungsten film 20 and connected to the plug 6B is formed within the bit line contact hole 17, and a plate contact 22 made of the second titanium nitride film 19 and the tungsten film 20 and connected to the first titanium nitride film 15 corresponding to the upper electrode is formed within the plate contact hole 18. Thereafter, interconnect layers 23 respectively connected to the bit line contact 21 and the plate contact 22 are formed on the third interlayer insulating film 16. In this manner, a DRAM memory cell is completed.

### SUMMARY OF THE INVENTION

The aforementioned conventional semiconductor device and the fabrication method for the same have, however, the following problem:

Charge is stored in the first titanium nitride film 15 corresponding to the upper electrode by plasma, which is used in the processes performed after forming the capacitor such as the etching for forming the plate contact hole 18 in the first titanium nitride film 15 corresponding to the upper electrode, the deposition of the second titanium nitride film 19 and the formation of the interconnect layers 23. In this case, since the first titanium nitride film 15 is not electrically connected to the silicon substrate 50, the charge stored in the first titanium nitride film 15 flows into the silicon substrate 50 merely through the tantalum oxide film 14 used as the capacitor dielectric film. As a result, the tantalum oxide film 14 is damaged, and hence, there arises a problem that the characteristics of the capacitor such as a charge holding property and reliability are largely degraded.

FIG. 25 is a diagram for showing dependency of a capacitor leakage current on a plate voltage (a voltage applied to the upper electrode). In FIG. 25, the abscissa indicates the voltage applied to the upper electrode (wherein “+” indicates a plate having a higher potential and “−” indicates the plate having a lower potential), and the ordinate indicates the leakage current flowing from the upper electrode to the lower electrode through the capacitor dielectric film of the tantalum oxide film 14.

As shown in FIG. 25, as compared with a capacitor leakage current characteristic obtained immediately after forming the upper electrode (namely, immediately after the etching of the first titanium nitride film 15), a leakage current is obviously increased in a capacitor leakage current characteristic obtained after forming the interconnect layers 23.

In consideration of the aforementioned problem, an object of the invention is preventing the increase of a capacitor leakage current by suppressing the degradation of a capacitor dielectric film by reducing the plasma damage of the capacitor dielectric film caused in forming a contact plug, an interconnect layer or the like after forming a capacitor.

In order to achieve the object, the semiconductor device of this invention includes a first insulating film formed on a semiconductor substrate; a second insulating film formed on the first insulating film and having a recess corresponding to a capacitor region; a lower electrode formed within the recess; a capacitor dielectric film formed on the lower electrode; an upper electrode formed on the capacitor dielectric film; and a conductive portion formed on the first insulating film and the second insulating film for electrically connecting the semiconductor substrate to the upper electrode.

The semiconductor device of the invention may further include an impurity layer formed in a surface portion of the semiconductor substrate; a third insulating film formed on the upper electrode and the second insulating film; and an interconnect formed on the third insulating film, and the conductive portion may include a first plug formed in the first insulating film and connected to the impurity layer; and a second plug formed in the second insulating film and the third insulating film and connected to the first plug, the upper electrode and the interconnect.

The semiconductor device of the invention may further include an impurity layer formed in a surface portion of the semiconductor substrate; a third insulating film formed on the upper electrode and the second insulating film; and an interconnect formed on the third insulating film, and the conductive portion may be a plug formed in the first insulating film, the second insulating film and the third insulating film and connected to the impurity layer, the upper electrode and the interconnect.

The semiconductor device of the invention may further include an impurity layer formed in a surface portion of the semiconductor substrate, and the conductive portion may include a plug formed in the first insulating film and connected to the impurity layer; and a dummy lower electrode formed in another recess formed in the second insulating film and connected to the plug, and the upper electrode may be formed also on the dummy lower electrode without providing the capacitor dielectric film therebetween.

The semiconductor device of the invention may further include an impurity layer formed in a surface portion of the semiconductor substrate; a third insulating film formed on the upper electrode and the second insulating film; and an interconnect formed on the third insulating film, and the conductive portion may include a first plug formed in the first insulating film and connected to the impurity layer; a dummy lower electrode formed in another recess formed in the second insulating film and connected to the first plug; and a second plug formed in at least the third insulating film and connected to the dummy lower electrode, the upper electrode and the interconnect, and the capacitor dielectric film and the upper electrode may be formed also on the dummy lower electrode.

The first method for fabricating a semiconductor device of this invention includes the steps of forming an impurity layer in a surface portion of a semiconductor substrate; forming a first insulating film on the semiconductor substrate including the impurity layer; forming, in the first insulating film, a first plug connected to the impurity layer; forming a second insulating film on the first insulating film including the first plug; forming a recess corresponding to a capacitor region in the second insulating film; forming a lower electrode in the recess; forming a capacitor dielectric film on the lower electrode; forming an upper electrode on the capacitor dielectric film; forming a third insulating film on the upper electrode and the second insulating film; forming, in the second insulating film and the third insulating film, a second plug connected to the first plug and the upper electrode; and forming, on the third insulating film, an interconnect connected to the second plug.

The second method for fabricating a semiconductor device of the invention includes the steps of forming an impurity layer in a surface portion of a semiconductor substrate; forming a first insulating film on the semiconductor substrate including the impurity layer; forming a second insulating film on the first insulating film; forming, in the second insulating film, a recess corresponding to a capacitor region; forming a lower electrode in the recess; forming a capacitor dielectric film on the lower electrode; forming an upper electrode on the capacitor dielectric film; forming a third insulating film on the upper electrode and the second insulating film; forming, in the first insulating film, the second insulating film and the third insulating film, a plug connected to the impurity layer and the upper electrode; and forming, on the third insulating film, an interconnect connected to the plug.

The third method for fabricating a semiconductor device of this invention includes the steps of forming an impurity layer in a surface portion of a semiconductor substrate; forming a first insulating film on the semiconductor substrate including the impurity layer; forming, in the first insulating film, a plug connected to the impurity layer; forming a second insulating film on the first insulating film including the plug; forming, in the second insulating film, a first recess corresponding to a capacitor region and a second recess reaching the plug; forming a lower electrode in the first recess and forming, in the second recess, a dummy lower electrode connected to the plug; forming a capacitor dielectric film on the lower electrode; and forming an upper electrode on the capacitor dielectric film and the dummy lower electrode.

The fourth method for fabricating a semiconductor device of the invention includes the steps of forming an impurity layer in a surface portion of a semiconductor substrate; forming a first insulating film on the semiconductor substrate including the impurity layer; forming, in the first insulating film, a first plug connected to the impurity layer; forming a second insulating film on the first insulating film including the first plug; forming, in the second insulating film, a first recess corresponding to a capacitor region and a second recess reaching the first plug; forming a lower electrode in the first recess and forming, in the second recess, a dummy lower electrode connected to the first plug; forming a capacitor dielectric film on the lower electrode and the dummy lower electrode; forming an upper electrode on the capacitor dielectric film; forming a third insulating film on the upper electrode and the second insulating film; forming, at least in the third insulating film, a second plug connected to the dummy lower electrode and the upper electrode; and forming, on the third insulating film, an interconnect connected to the second plug.

According to this invention, the capacitor upper electrode is electrically connected to the semiconductor substrate even during the fabrication of the semiconductor device, and therefore, charge stored in the upper electrode can be prevented from flowing to the semiconductor substrate through the capacitor dielectric film. Accordingly, since the process damage of the capacitor dielectric film caused after forming the upper electrode can be reduced, the degradation of the capacitor dielectric film can be suppressed so as to prevent the increase of a capacitor leakage current.

As described so far, the present invention relates to a semiconductor device and a fabrication method for the same, and in the application to a semiconductor memory device including a capacitor, the invention is very useful for suppressing the degradation of a capacitor dielectric film so as to prevent the increase of a capacitor leakage current.

### BRIEF DESCRIPTION OF THE DRAWINGS

FIGS. 1A, 1B and 1C are cross-sectional views for showing procedures in a method for fabricating a semiconductor device according to Embodiment 1 of the invention;

FIGS. 2A, 2B and 2C are cross-sectional views for showing other procedures in the method for fabricating a semiconductor device according to Embodiment 1 of the invention;

FIGS. 3A, 3B and 3C are cross-sectional views for showing other procedures in the method for fabricating a semiconductor device according to Embodiment 1 of the invention;

FIGS. 4A and 4B are cross-sectional views for showing other procedures in the method for fabricating a semiconductor device according to Embodiment 1 of the invention;

FIGS. 5A and 5B are cross-sectional views for showing other procedures in the method for fabricating a semiconductor device according to Embodiment 1 of the invention;

FIG. 6 is a diagram for showing comparison between dependency of a leakage current on a plate voltage obtained in a capacitor formed by the method for fabricating a semiconductor device of Embodiment 1 and dependency of a leakage current on a plate voltage obtained in a capacitor formed by a conventional technique;

FIGS. 7A, 7B and 7C are cross-sectional views for showing procedures in a method for fabricating a semiconductor device according to Embodiment 2 of the invention;

FIGS. 8A, 8B and 8C are cross-sectional views for showing other procedures in the method for fabricating a semiconductor device according to Embodiment 2 of the invention;

FIGS. 9A, 9B and 9C are cross-sectional views for showing other procedures in the method for fabricating a semiconductor device according to Embodiment 2 of the invention;

FIGS. 10A and 10B are cross-sectional views for showing other procedures in the method for fabricating a semiconductor device according to Embodiment 2 of the invention;

FIGS. 11A and 11B are cross-sectional views for showing other procedures in the method for fabricating a semiconductor device according to Embodiment 2 of the invention;

FIGS. 12A, 12B and 12C are cross-sectional views for showing procedures in a method for fabricating a semiconductor device according to Embodiment 3 of the invention;

FIGS. 13A, 13B and 13C are cross-sectional views for showing other procedures in the method for fabricating a semiconductor device according to Embodiment 3 of the invention;

FIGS. 14A and 14B are cross-sectional views for showing other procedures in the method for fabricating a semiconductor device according to Embodiment 3 of the invention;

FIGS. 15A, 15B and 15C are cross-sectional views for showing other procedures in the method for fabricating a semiconductor device according to Embodiment 3 of the invention;

FIGS. 16A, 16B and 16C are cross-sectional views for showing procedures in a method for fabricating a semiconductor device according to Embodiment 4 of the invention;

FIGS. 17A and 17B are cross-sectional views for showing other procedures in the method for fabricating a semiconductor device according to Embodiment 4 of the invention;

FIGS. 18A and 18B are cross-sectional views for showing other procedures in the method for fabricating a semiconductor device according to Embodiment 4 of the invention;

FIG. 19 is a cross-sectional view of a semiconductor device according to a modification of Embodiment 4 of the invention;

FIGS. 20A, 20B and 20C are cross-sectional views for showing procedures in a method for fabricating a conventional semiconductor device;

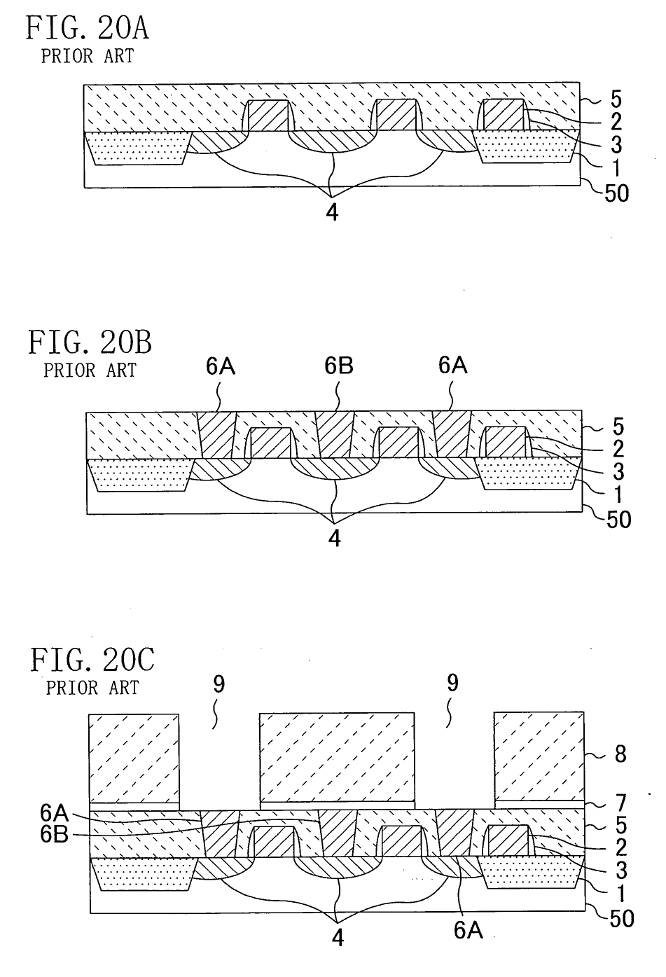

FIGS. 21A, 21B and 21C are cross-sectional views for showing other procedures in the method for fabricating the conventional semiconductor device;

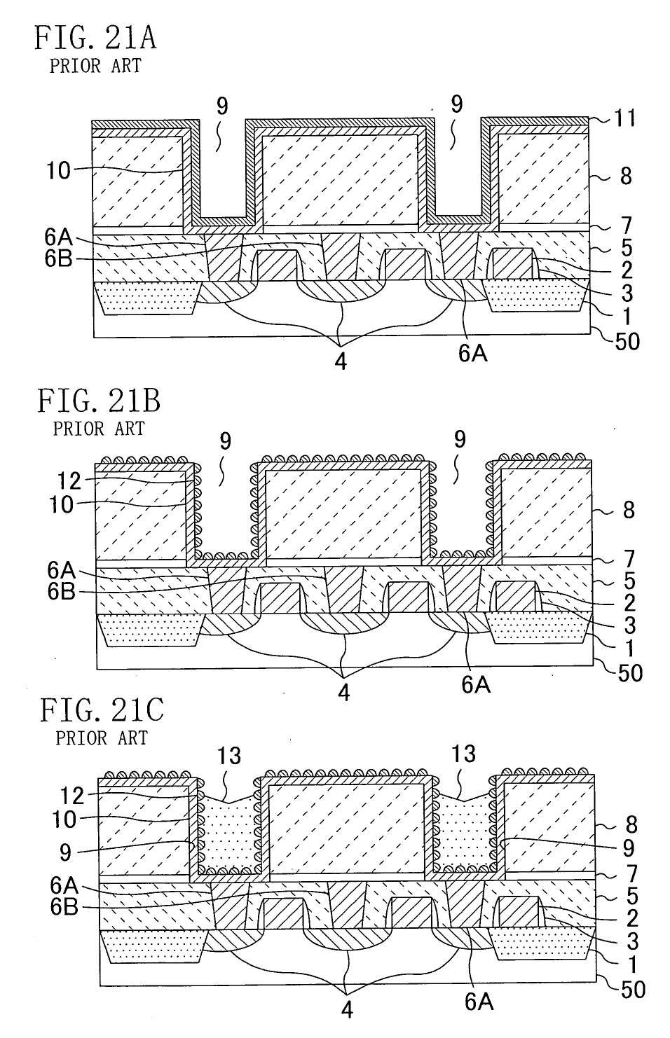

FIGS. 22A, 22B and 22C are cross-sectional views for showing other procedures in the method for fabricating the conventional semiconductor device;

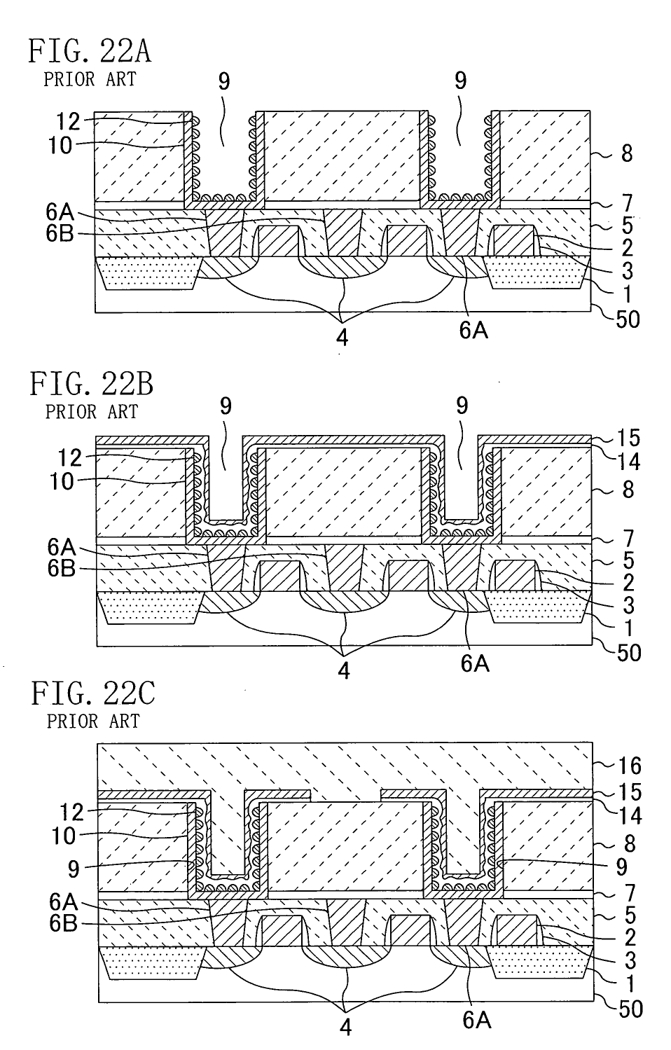

FIGS. 23A and 23B are cross-sectional views for showing other procedures in the method for fabricating the conventional semiconductor device;

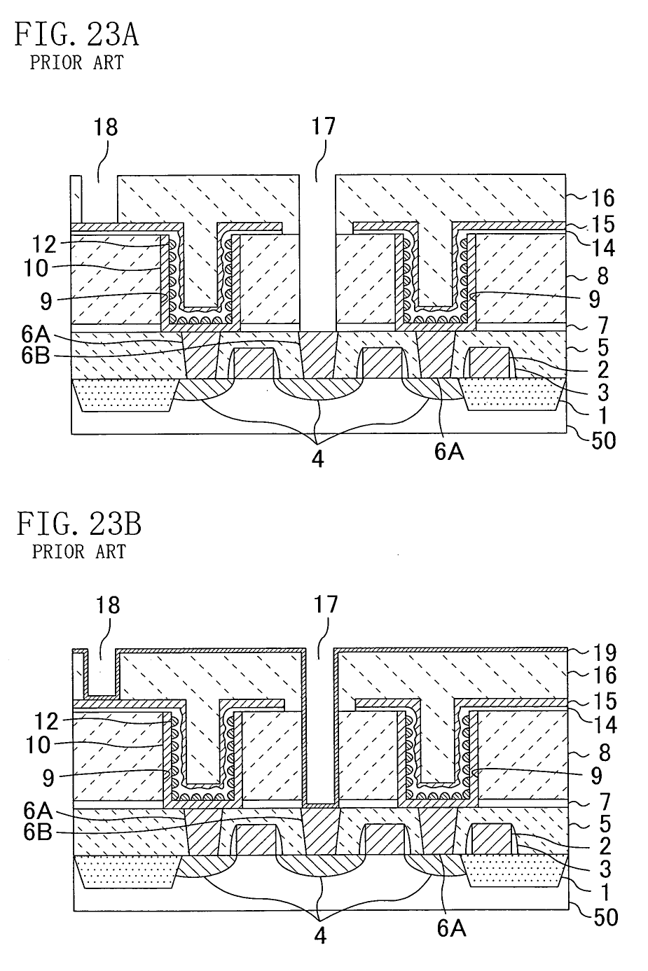

FIGS. 24A and 24B are cross-sectional views for showing other procedures in the method for fabricating the conventional semiconductor device; and

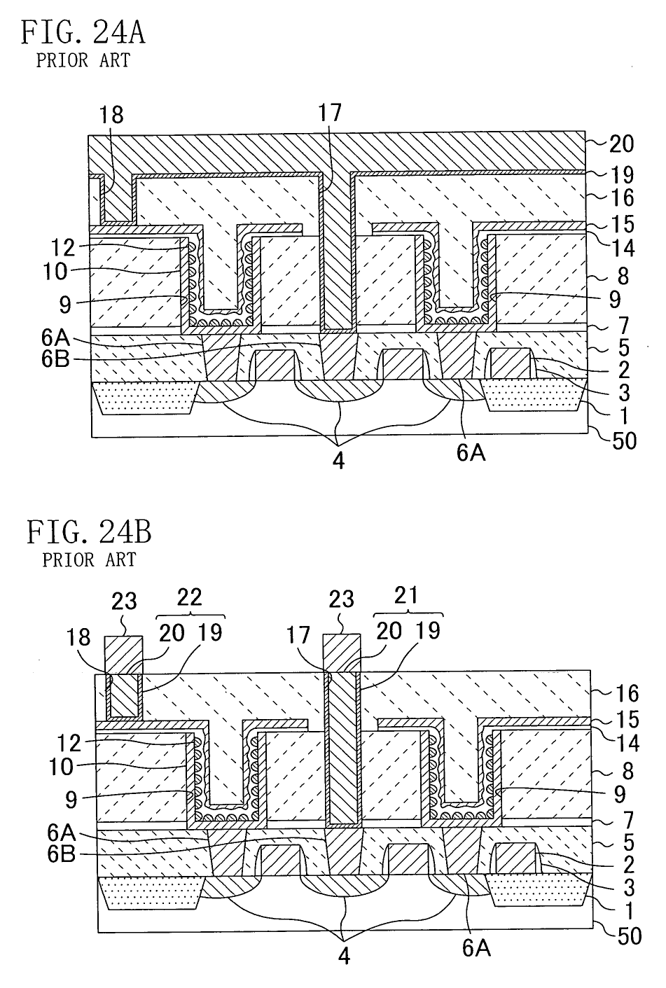

FIG. 25 is a diagram for showing dependency of a leakage current on a plate voltage obtained in a capacitor included in the conventional semiconductor device.

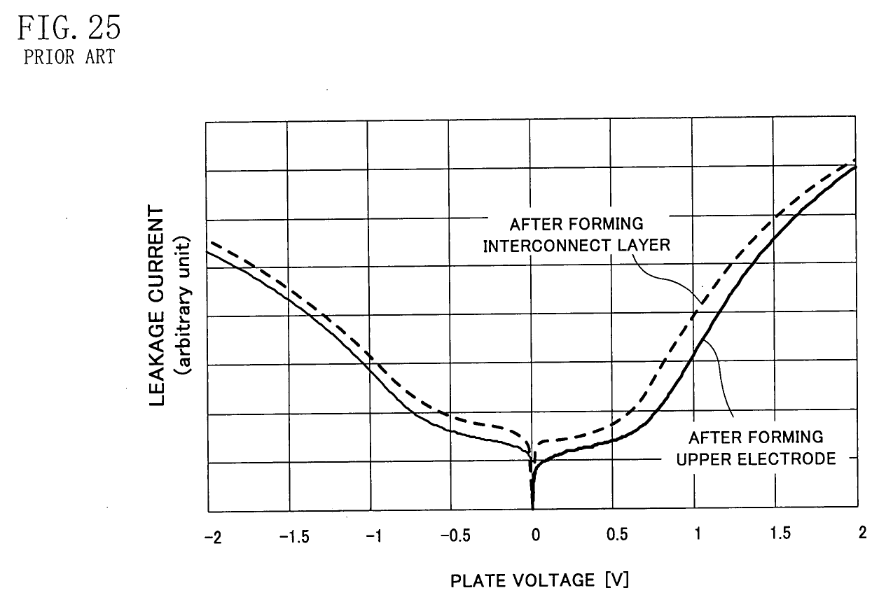

### DETAILED DESCRIPTION OF THE INVENTION

### Embodiment 1

Now, a semiconductor device and a method for fabricating the semiconductor device according to Embodiment 1 of the invention will be described with reference to the accompanying drawings.

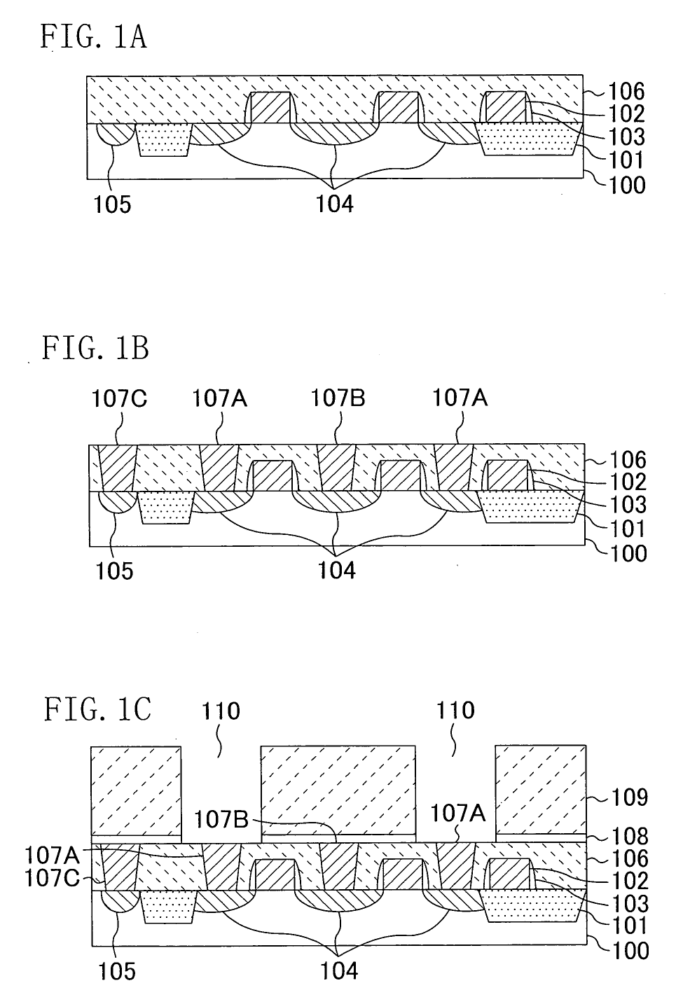

FIGS. 1A through 1C, 2A through 2C, 3A through 3C, 4A, 4B, 5A and 5B are cross-sectional views for showing procedures in the method for fabricating the semiconductor device of Embodiment 1.

First, as shown in FIG. 1A, after forming a shallow trench isolation region 101 in a semiconductor substrate 100 of, for example, silicon, a p-type impurity such as boron (B) is implanted into the semiconductor substrate 100 at energy of 15 keV and a dose of approximately 8×10¹²/cm² for controlling a threshold voltage of a DRAM cell transistor. Next, a gate insulating film (not shown) with a thickness of, for example, 7.5 nm and a first polysilicon film with a thickness of, for example, 200 nm are successively deposited on the semiconductor substrate 100, and then, the first polysilicon film is patterned by lithography and dry etching, thereby forming a gate electrode 102. Then, after forming a resist film (not shown) having an opening in a memory cell region alone by the lithography, an n-type impurity such as phosphorus (P) is implanted into the semiconductor substrate 100 by ion implantation at energy of 10 keV and a dose of approximately 2×10¹³/cm² by using the resist film and the gate electrode 102 as a mask. Thus, LDD regions 104 corresponding to source/drain regions (of N-type) of the memory cell transistor and an N-type impurity diffusion layer 105 are formed. It is noted that the shallow trench isolation region 101 is present between the LDD region 104 and the impurity diffusion layer 105.

Thereafter, an insulating film such as a TEOS film is deposited over the whole semiconductor substrate 100 by CVD, and the insulating film is etched by anisotropic dry etching, thereby forming an insulating sidewall 103 on the side face of the gate electrode 102. Next, a first interlayer insulating film 106 with a thickness of approximately 800 nm of, for example, an NSG (non-doped silicate glass) film is formed over the whole semiconductor substrate 100 by the CVD. Then, the first interlayer insulating film 106 is polished by a thickness of approximately 200 nm by CMP (chemical mechanical polishing) so as to planarize the surface of the first interlayer insulating film 106.

Next, as shown in FIG. 1B, a plurality of contact holes reaching the LDD regions 104 of the DRAM cell transistor and a contact hole reaching the impurity diffusion layer 105 are formed in the first interlayer insulating film 106 by the lithography and the dry etching. Then, a plug 107A to be connected to a capacitor lower electrode or a plug 107B to be connected to an interconnect (bit line) is formed within each contact hole reaching the LDD region 104, and a plug 107C to be connected to a capacitor upper electrode is formed within the contact hole reaching the impurity diffusion layer 105. The plugs 107A through 107C are specifically formed as follows: First, naturally oxidized films formed on the LDD regions 104 and the impurity diffusion layer 105 exposed on the bottoms of the contact holes are removed by wet etching using a cleaning fluid including hydrofluoric acid. Then, a low-resistance polysilicon film doped with an n-type impurity such as P (phosphorus) is deposited by the CVD on the first interlayer insulating film 106 including the insides of the contact holes. Subsequently, a portion of the polysilicon film deposited outside the contact holes is removed by polishing through the CMP, thereby forming the plugs 107A through 107C.

Next, as shown in FIG. 1C, a silicon nitride film 108 with a thickness of, for example, 50 nm and a second interlayer insulating film 109 with a thickness of approximately 700 nm of, for example, a BPSG (boro-phospho silicate glass) film are successively deposited by the CVD on the first interlayer insulating film 106 including the plugs 107A through 107C. Then, after forming a photoresist film (not shown) having an opening in a capacitor region on the second interlayer insulating film 109 by the lithography, the second interlayer insulating film 109 and the silicon nitride film 108 are successively etched by the dry etching by using the photoresist film as a mask, thereby forming a recess 110 for forming a capacitor. At this point, the top face of the plug 107A is exposed on the bottom of the recess 110.

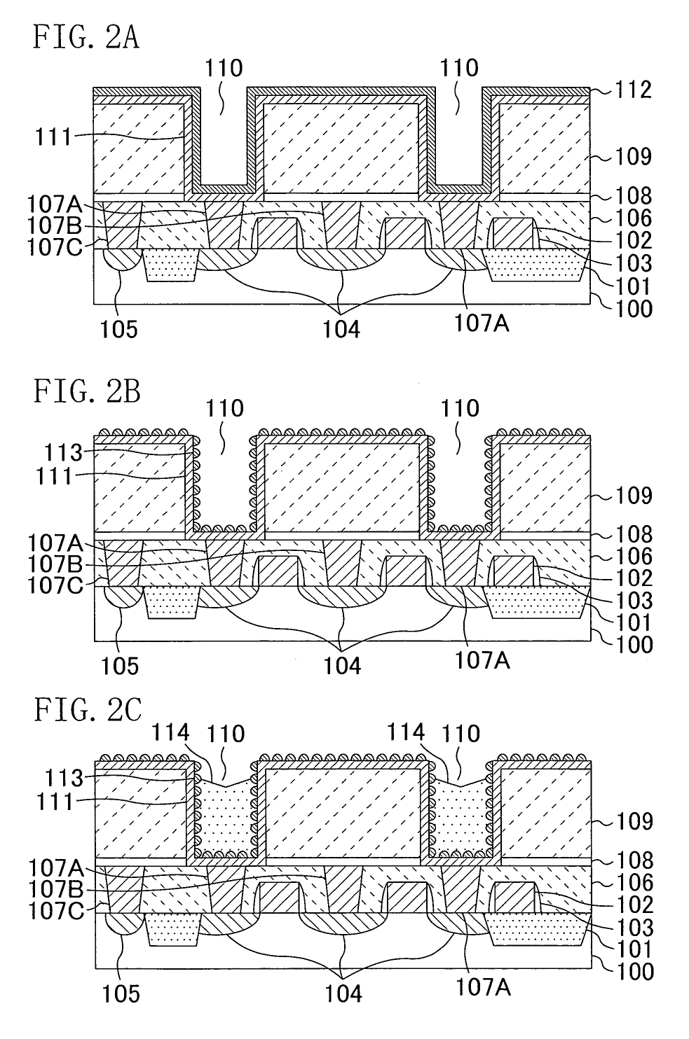

Next, after removing native oxide formed on the plug 107A exposed within the recess 110 by the wet etching using a cleaning fluid including hydrofluoric acid, a second polysilicon film 111 doped with an n-type impurity such as P (phosphorus) is deposited by the CVD on the second interlayer insulating film 109 including the recess 110 as shown in FIG. 2A. Then, an amorphous silicon film 112 with a thickness of, for example, approximately 25 nm is deposited on the second polysilicon film 111.

Next, after removing native oxide formed on the amorphous silicon film 112 by using the cleaning fluid including hydrofluoric acid, the semiconductor substrate 100 is subjected to annealing while supplying monosilane (SiH₄) onto the surface of the amorphous silicon film 112 in a reduced pressure atmosphere, thereby polycrystallizing the amorphous silicon film 112 and growing silicon grains thereon. Thus, an HSG film 113 is formed on the second polysilicon film 111 as shown in FIG. 2B. Subsequently, the semiconductor substrate 100 is subjected to annealing at a temperature of, for example, 700° C. for 6 minutes in a gas atmosphere including PH₃, thereby doping the HSG film 113 with P. In this embodiment, this HSG film 113 doped with P is used as a lower electrode of a MIS capacitor of the DRAM.

Next, as shown in FIG. 2C, after applying a resist film on the HSG film 113, the whole resist film is subjected to exposure and development by the lithography, thereby allowing a resist film 114 to selectively remain merely within the recess 110 corresponding to the capacitor region.

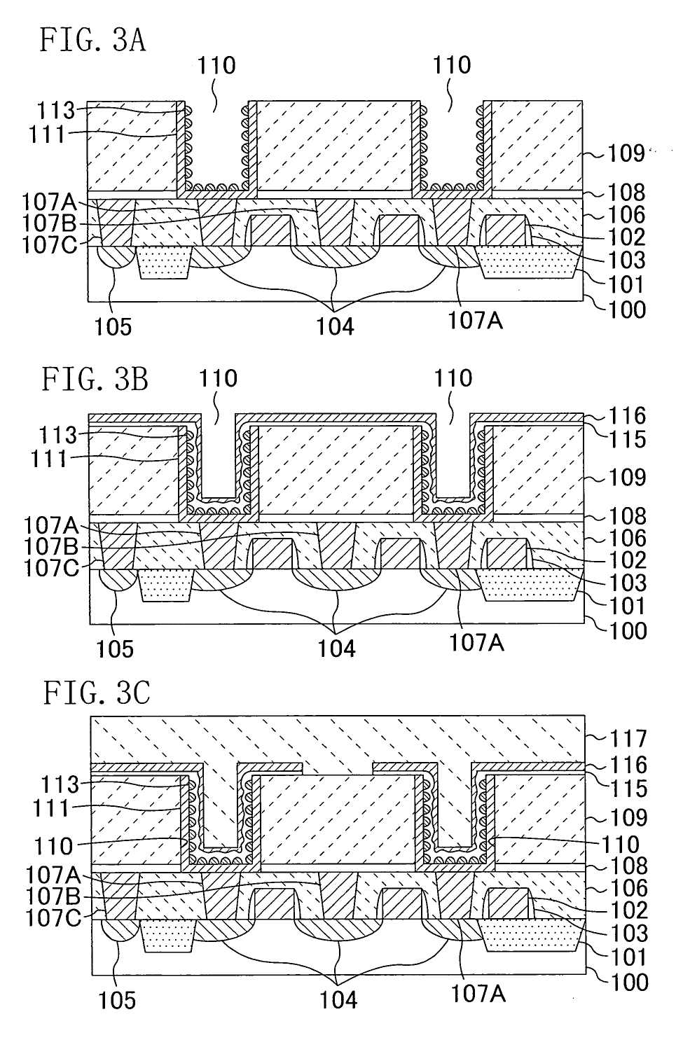

Next, after the HSG film 113 and the second polysilicon film 111 are subjected to the anisotropic etching by the dry etching with the resist film 114 used as a mask, the resist film 114 is removed by ashing using the dry etching and the wet etching. Thus, as shown in FIG. 3A, the HSG film 113 and the second polysilicon film 111 corresponding to the lower electrode can remain merely within the recess 110 corresponding to the capacitor region. At this point, the second polysilicon film 111 remaining within the recess 110 is connected to the plug 107A.

Next, after removing native oxide formed on the HSG film 113 by the wet etching using a cleaning fluid including hydrofluoric acid, the HSG film 113 is exposed to plasma of a nitrogen gas, thereby forming a nitride film (not shown) with a thickness of approximately 2 nm on the HSG film 113. This nitride film functions as an anti-oxidation film for the HSG film 113 in crystallization and reforming process of a tantalum oxide film performed in an oxidizing atmosphere described below.

Next, as shown in FIG. 3B, a tantalum oxide film 115 is deposited over the substrate, and the tantalum oxide film 115 is annealed at a temperature of, for example, 800° C. for 60 seconds in an oxygen atmosphere, thereby polycrystallizing the tantalum oxide film 115. Subsequently, a first titanium nitride film 116 is deposited on the tantalum oxide film 115 by the CVD using titanium chloride (TiCl₄) and ammonia (NH₃) as material gasses. In this embodiment, the first titanium nitride film 116 is used as an upper electrode of the capacitor of the DRAM.

Next, as shown in FIG. 3C, the tantalum oxide film 115 and the first titanium nitride film 116 are patterned by the lithography and the dry etching, thereby forming a capacitor dielectric film and the upper electrode on the lower electrode (namely, the HSG film 113 and the second polysilicon film 111), and thus, the capacitor is completed. It is noted that the first titanium nitride film 116 corresponding to the upper electrode extends, for plate contact, over the second interlayer insulating film 109 provided in the vicinity of the recess 110 corresponding to the capacitor region.

Thereafter, a third interlayer insulating film 117 is deposited by plasma CVD on the second interlayer insulating film 109 including the first titanium nitride film 116 corresponding to the upper electrode, and the surface of the third interlayer insulating film 117 is planarized.

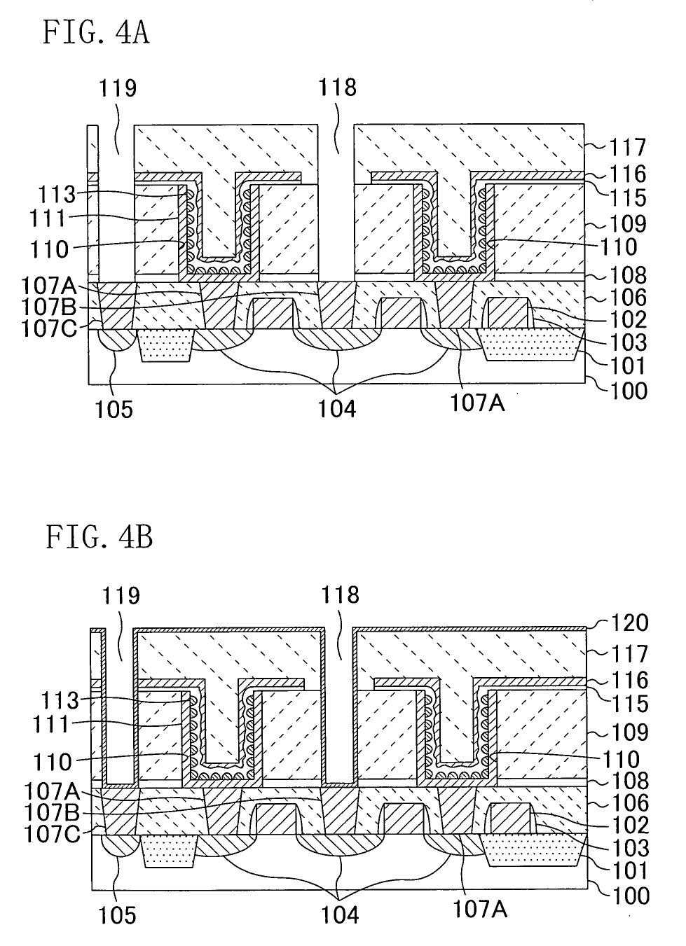

Next, after a photoresist film (not shown) having openings in a bit line contact region and a plate contact region alone is formed on the third interlayer insulating film 117 by the lithography, the third interlayer insulating film 117, the second interlayer insulating film 109 and the silicon nitride film 108 are successively etched by the dry etching by using the photoresist film as a mask as shown in FIG. 4A, thereby forming a bit line contact hole 118 reaching the plug 107B. Simultaneously, in the plate contact region, the third interlayer insulating film 117, the first titanium nitride film 116, the second interlayer insulating film 109 and the silicon nitride film 108 are successively etched, thereby forming a plate contact hole 119 reaching the plug 107C.

Next, as shown in FIG. 4B, a second titanium nitride film 120 working as an adhesion layer is deposited by the CVD at a wafer temperature of 700° C. on the third interlayer insulating film 117 and within the bit line contact hole 118 and the plate contact hole 119.

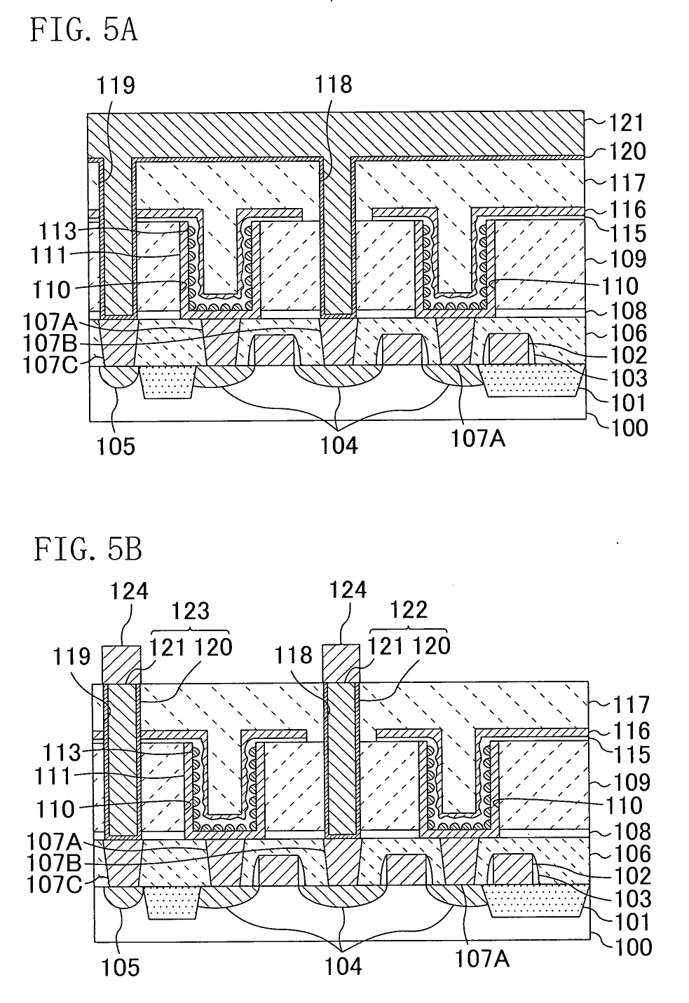

Next, as shown in FIG. 5A, a tungsten film 121 is deposited by the CVD on the second titanium nitride film 120 so as to completely fill the bit line contact hole 118 and the plate contact hole 119.

Next, as shown in FIG. 5B, portions of the second titanium nitride film 120 and the tungsten film 121 deposited outside the bit line contact hole 118 and the plate contact hole 119, namely, unnecessary portions of the second titanium nitride film 120 and the tungsten film 121 disposed on the third interlayer insulating film 117, are removed by polishing by the CMP. Thus, a bit line contact 122 made of the second titanium nitride film 120 and the tungsten film 121 and connected to the plug 107B is formed within the bit line contact hole 118. Also, a plate contact 123 made of the second titanium nitride film 120 and the tungsten film 121 and connected to the plug 107C and the first titanium nitride film 116 corresponding to the upper electrode is formed within the plate contact hole 119. Thereafter, interconnect layers 124 respectively connected to the bit line contact 122 and the plate contact 123 are formed on the third interlayer insulating film 117. In this manner, the DRAM memory cell is completed.

In this manner, in the DRAM memory cell of this embodiment, the contact connected to the first titanium nitride film 116 corresponding to the capacitor upper electrode (namely, the plate contact 123) is connected to the N-type impurity diffusion layer 105, namely, the semiconductor substrate 100, through the plug 107C.

In this embodiment, the capacitor includes the lower electrode made of the second polysilicon film 111 and the HSG film 113, the capacitor dielectric film made of the tantalum oxide film 115 and the upper electrode made of the first titanium nitride film 116.

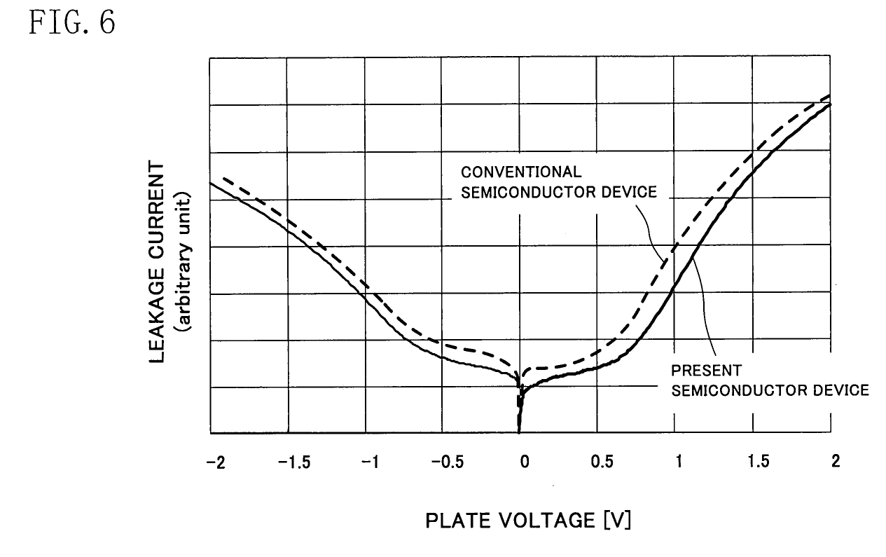

FIG. 6 is a diagram for showing comparison between dependency of a leakage current on a plate voltage (i.e., a voltage applied to the upper electrode) obtained in the capacitor formed by the method of this embodiment and dependency of a leakage current on a plate voltage obtained in a capacitor formed by a conventional technique.

As shown in FIG. 6, the leakage current caused in the capacitor of this embodiment is smaller than in the conventional capacitor. The reason seems to be the following:

In the conventional capacitor formed by the conventional technique, a plate contact is not connected to a semiconductor substrate but is connected to an upper electrode alone. Therefore, charge stored in the upper electrode by plasma, which is used in processes performed after forming the capacitor such as etching performed for forming a contact hole on a conductive film (such as a titanium nitride film) corresponding to the capacitor upper electrode, deposition of the conductive film and formation of an upper layer interconnect, flows into the semiconductor substrate merely through a capacitor dielectric film (of, for example, a tantalum oxide film). As a result, the capacitor dielectric film is damaged, and hence, the characteristics of the capacitor such as a charge holding property and reliability are largely degraded.

In contrast, in the semiconductor device of this embodiment, the first titanium nitride film 116 corresponding to the capacitor upper electrode is connected to the N-type impurity diffusion layer 105 and the semiconductor substrate 100 through the plate contact 123 and the plug 107C. In other words, the capacitor upper electrode is electrically connected to the semiconductor substrate 100 even during the fabrication of the semiconductor device. Therefore, charge stored in the upper electrode (i.e., the first titanium nitride film 116) by the plasma used in the processes such as the etching for forming the contact hole and the deposition of the second titanium nitride film flows into the semiconductor substrate 100 through the plate contact 123 and the plug 107C. In other words, the charge can be prevented from flowing to the semiconductor substrate 100 through the capacitor dielectric film (i.e., the tantalum oxide film 115). Accordingly, the process damage caused in the capacitor dielectric film can be reduced, and hence, the degradation of the capacitor dielectric film is suppressed so as to prevent increase of the capacitor leakage current. Specifically, the characteristics of the capacitor such as a charge holding property and reliability can be prevented from degrading.

In this embodiment, a voltage applied to the upper electrode is always a positive voltage and a voltage applied to the semiconductor substrate 100 is always 0 or a negative voltage. Therefore, PN junction formed between the N-type impurity diffusion layer 105 and the semiconductor substrate 100 that is doped with the p-type impurity for controlling the threshold voltage of the DRAM cell transistor is always placed in a negative bias state. Accordingly, an excessively large current never flows to the impurity diffusion layer 105 and the first titanium nitride film 116 corresponding to the upper electrode.

Also, in this embodiment, the bit line contact hole 118 and the plate contact hole 119 are formed by using the same resist pattern. Instead, the following method may be employed: After forming the bit line contact hole 118, a photoresist film having an opening in the plate contact region alone is formed by the lithography, and then, the third interlayer insulating film 117, the first titanium nitride film 116, the second interlayer insulating film 109 and the silicon nitride film 108 are successively etched with the photoresist film used as a mask, thereby forming the plate contact hole 119. Alternatively, after forming the plate contact hole 119, the bit line contact hole 118 may be formed by using a resist pattern having an opening in the bit line contact region alone.

### Embodiment 2

Now, a semiconductor device and a fabrication method for the semiconductor device according to Embodiment 2 of the invention will be described.

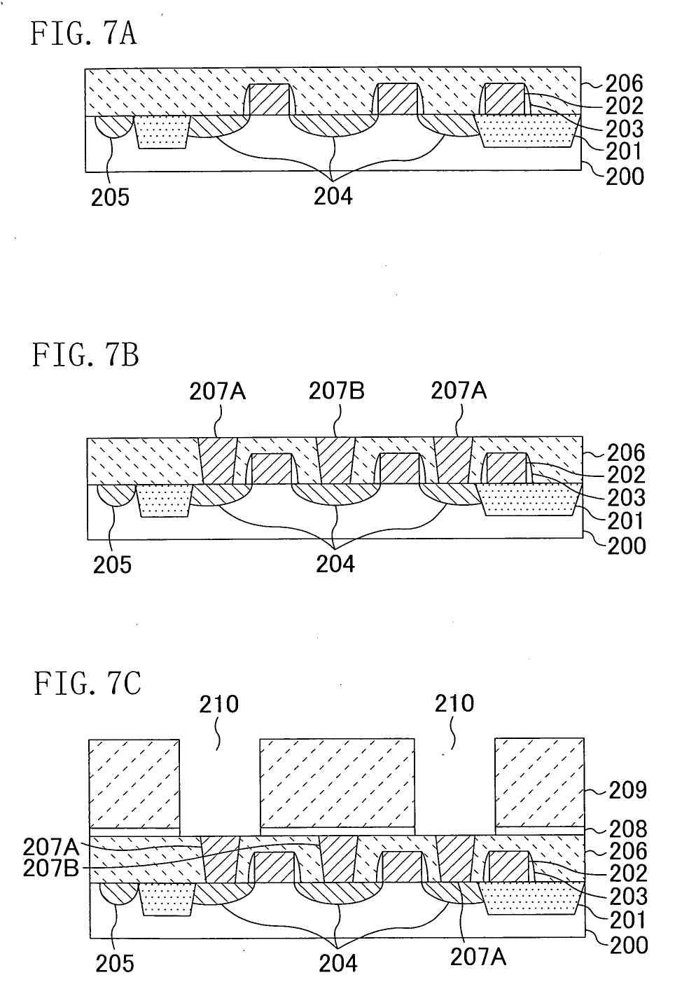

FIGS. 7A through 7C, 8A through 8C, 9A through 9C, 10A, 10B, 11A and 11B are cross-sectional views for showing procedures in the method for fabricating the semiconductor device of Embodiment 2.

First, as shown in FIG. 7A, after forming a shallow trench isolation region 201 in a semiconductor substrate 200 of, for example, silicon, a p-type impurity such as boron (B) is implanted into the semiconductor substrate 200 at energy of 15 keV and a dose of approximately 8×10¹²/cm² for controlling a threshold voltage of a DRAM cell transistor. Next, a gate insulating film (not shown) with a thickness of, for example, 7.5 nm and a first polysilicon film with a thickness of, for example, 200 nm are successively deposited on the semiconductor substrate 200, and then, the first polysilicon film is patterned by the lithography and the dry etching, thereby forming a gate electrode 202. Then, after forming a resist film (not shown) having an opening in a memory cell region alone by the lithography, an n-type impurity such as phosphorus (P) is implanted into the semiconductor substrate 200 by the ion implantation at energy of 10 keV and a dose of approximately 2×10¹³/cm² by using the resist film and the gate electrode 202 as a mask. Thus, LDD regions 204 corresponding to source/drain regions (of N-type) of the memory cell transistor and an N-type impurity diffusion layer 205 are formed. It is noted that the shallow trench isolation region 201 is present between the LDD region 204 and the impurity diffusion layer 205.

Thereafter, an insulating film such as a TEOS film is deposited over the whole semiconductor substrate 200 by the CVD, and the insulating film is etched by the anisotropic dry etching, thereby forming an insulating sidewall 203 on the side face of the gate electrode 202. Next, a first interlayer insulating film 206 with a thickness of approximately 800 nm of, for example, an NSG film is formed over the whole semiconductor substrate 200 by the CVD. Then, the first interlayer insulating film 206 is polished by a thickness of approximately 200 nm by the CMP so as to planarize the surface of the first interlayer insulating film 206.

Next, as shown in FIG. 7B, a plurality of contact holes reaching the LDD regions 204 of the DRAM cell transistor are formed in the first interlayer insulating film 206 by the lithography and the dry etching. Then, a plug 207A to be connected to a capacitor lower electrode or a plug 207B to be connected to an interconnect (bit line) is formed within each contact hole reaching the LDD region 204. The plugs 207A and 207B are specifically formed as follows: First, native oxide formed on the LDD regions 204 exposed on the bottoms of the contact holes is removed by the wet etching using a cleaning fluid including hydrofluoric acid. Then, a low-resistance polysilicon film doped with an n-type impurity such as P (phosphorus) is deposited by the CVD on the first interlayer insulating film 206 including the insides of the contact holes. Subsequently, a portion of the polysilicon film deposited outside the contact holes is removed by polishing through the CMP, thereby forming the plugs 207A and 207B.

Next, as shown in FIG. 7C, a silicon nitride film 208 with a thickness of, for example, 50 nm and a second interlayer insulating film 209 with a thickness of approximately 700 nm of, for example, a BPSG film are successively deposited by the CVD on the first interlayer insulating film 206 including the plugs 207A and 207B. Then, after forming a photoresist film (not shown) having an opening in a capacitor region on the second interlayer insulating film 209 by the lithography, the second interlayer insulating film 209 and the silicon nitride film 208 are successively etched by the dry etching by using the photoresist film as a mask, thereby forming a recess 210 for forming a capacitor. At this point, the top face of the plug 207A is exposed on the bottom of the recess 210.

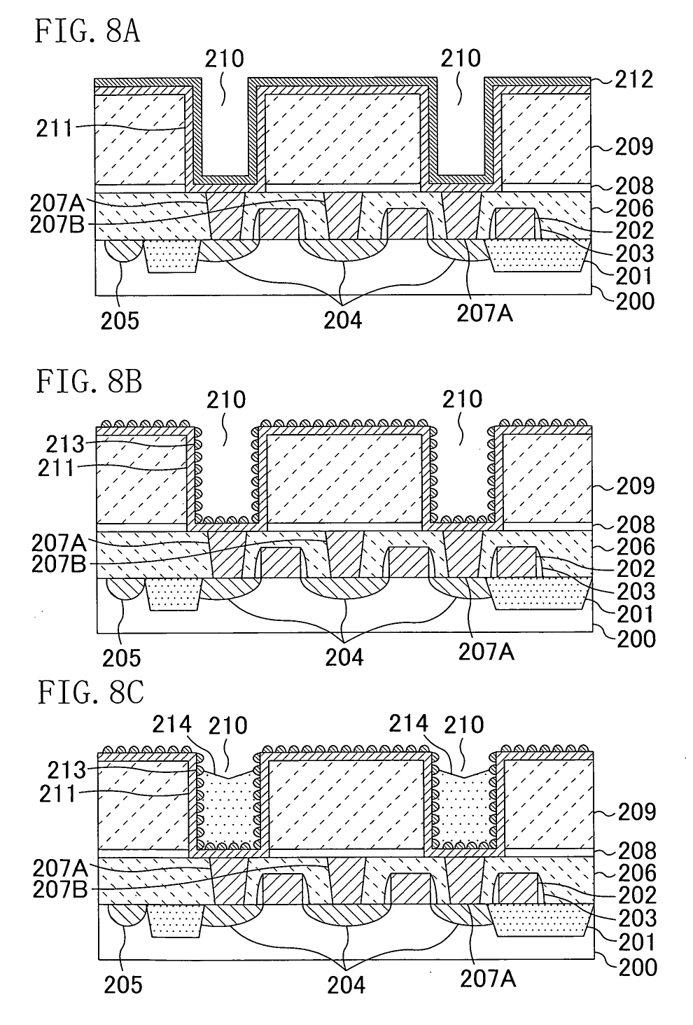

Next, after removing native oxide formed on the plug 207A exposed within the recess 210 by the wet etching using a cleaning fluid including hydrofluoric acid, a second polysilicon film 211 doped with an n-type impurity such as P (phosphorus) is deposited by the CVD on the second interlayer insulating film 209 including the recess 210 as shown in FIG. 8A. Then, an amorphous silicon film 212 with a thickness of, for example, approximately 25 nm is deposited on the second polysilicon film 211.

Next, after removing native oxide formed on the amorphous silicon film 212 by using a cleaning fluid including hydrofluoric acid, the semiconductor substrate 200 is subjected to annealing while supplying monosilane (SiH₄) onto the surface of the amorphous silicon film 212 in a reduced pressure atmosphere, thereby polycrystallizing the amorphous silicon film 212 and growing silicon grains thereon. Thus, an HSG film 213 is formed on the second polysilicon film 211 as shown in FIG. 8B. Subsequently, the semiconductor substrate 200 is subjected to annealing at a temperature of, for example, 700° C. for 6 minutes in a gas atmosphere including PH₃, thereby doping the HSG film 213 with P. In this embodiment, this HSG film 213 doped with P is used as a lower electrode of a MIS capacitor of the DRAM.

Next, as shown in FIG. 8C, after applying a resist film on the HSG film 213, the whole resist film is subjected to the exposure and the development by the lithography, thereby allowing a resist film 214 to selectively remain merely within the recess 210 corresponding to the capacitor region.

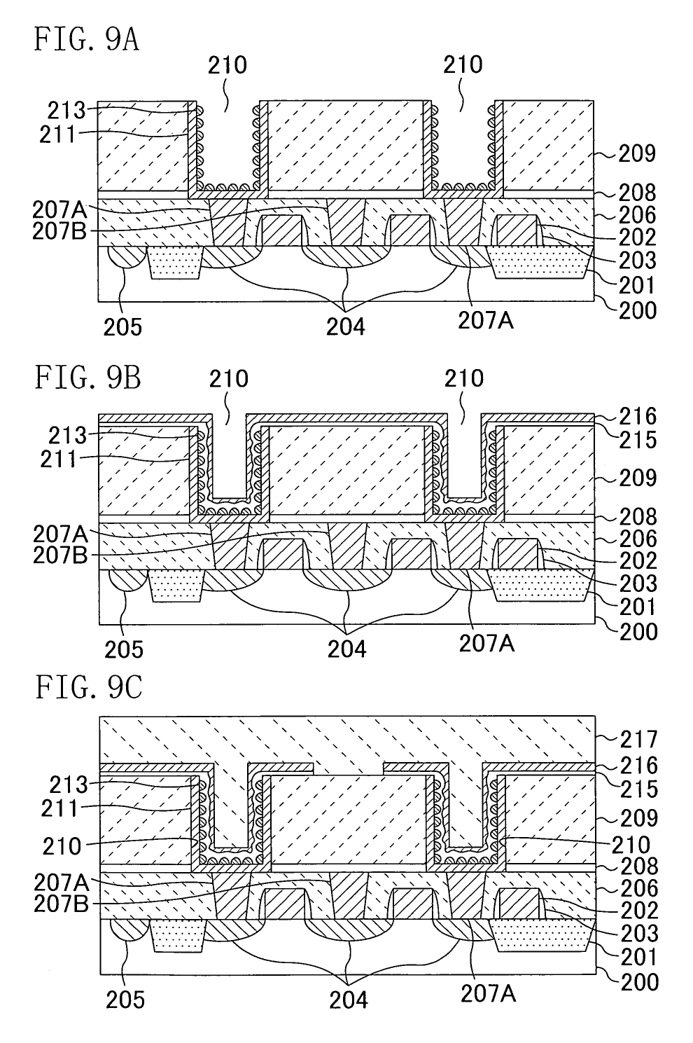

Next, after the HSG film 213 and the second polysilicon film 211 are subjected to the anisotropic etching by the dry etching with the resist film 214 used as a mask, the resist film 214 is removed by the ashing using the dry etching and the wet etching. Thus, as shown in FIG. 9A, the HSG film 213 and the second polysilicon film 211 corresponding to the lower electrode can remain merely within the recess 210 corresponding to the capacitor region. At this point, the second polysilicon film 211 remaining within the recess 210 is connected to the plug 207A.

Next, after removing native oxide formed on the HSG film 213 by the wet etching using a cleaning fluid including hydrofluoric acid, the HSG film 213 is exposed to plasma of a nitrogen gas, thereby forming a nitride film (not shown) with a thickness of approximately 2 nm on the HSG film 213. This nitride film functions as an anti-oxidation film for the HSG film 213 in crystallization and reforming process of a tantalum oxide film performed in an oxidizing atmosphere described below.

Next, as shown in FIG. 9B, a tantalum oxide film 215 is deposited over the substrate, and the tantalum oxide film 215 is annealed at a temperature of, for example, 800° C. for 60 seconds in an oxygen atmosphere, thereby polycrystallizing the tantalum oxide film 215. Subsequently, a first titanium nitride film 216 is deposited on the tantalum oxide film 215 by the CVD using titanium chloride (TiCl₄) and ammonia (NH₃) as material gasses. In this embodiment, the first titanium nitride film 216 is used as an upper electrode of the capacitor of the DRAM.

Next, as shown in FIG. 9C, the tantalum oxide film 215 and the first titanium nitride film 216 are patterned by the lithography and the dry etching, thereby forming a capacitor dielectric film and the upper electrode on the lower electrode (namely, the HSG film 213 and the second polysilicon film 211), and thus, the capacitor is completed. It is noted that the first titanium nitride film 216 corresponding to the upper electrode extends, for plate contact, over the second interlayer insulating film 209 provided in the vicinity of the recess 210 corresponding to the capacitor region.

Thereafter, a third interlayer insulating film 217 is deposited by the plasma CVD on the second interlayer insulating film 209 including the first titanium nitride film 216 corresponding to the upper electrode, and the surface of the third interlayer insulating film 217 is planarized by polishing it by a thickness of approximately 300 nm by the CMP.

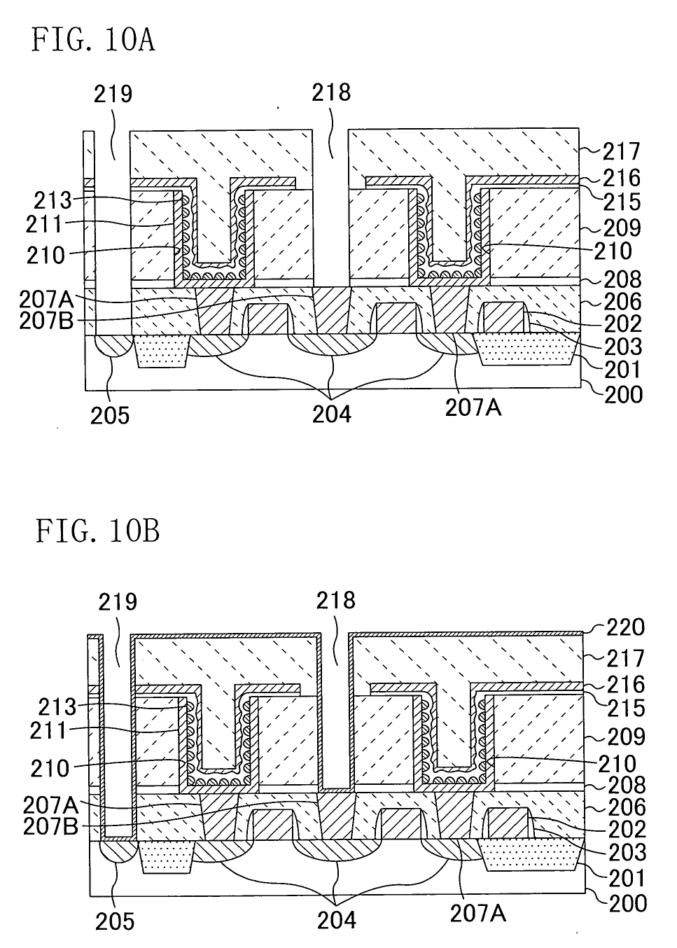

Next, after a photoresist film (not shown) having openings in a bit line contact region and a plate contact region alone is formed on the third interlayer insulating film 217 by the lithography, the third interlayer insulating film 217, the second interlayer insulating film 209 and the silicon nitride film 208 are successively etched by the dry etching by using the photoresist film as a mask as shown in FIG. 10A, thereby forming a bit line contact hole 218 reaching the plug 207B. Simultaneously, in the plate contact region, the third interlayer insulating film 217, the first titanium nitride film 216, the second interlayer insulating film 209, the silicon nitride film 208 and the first interlayer insulating film 206 are successively etched, thereby forming a plate contact hole 219 reaching the N-type impurity diffusion layer 205.

Next, as shown in FIG. 10B, a second titanium nitride film 220 working as an adhesion layer is deposited by the CVD at a wafer temperature of 700° C. on the third interlayer insulating film 217 and within the bit line contact hole 218 and the plate contact hole 219.

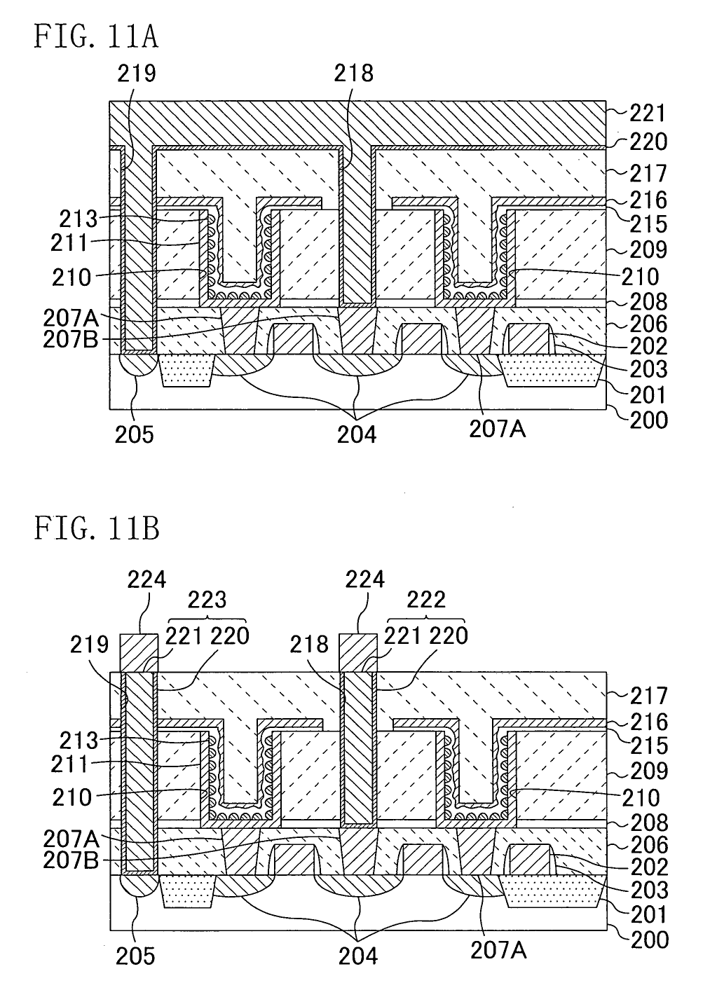

Next, as shown in FIG. 11A, a tungsten film 221 is deposited by the CVD on the second titanium nitride film 220 so as to completely fill the bit line contact hole 218 and the plate contact hole 219.

Next, as shown in FIG. 11B, portions of the second titanium nitride film 220 and the tungsten film 221 deposited outside the bit line contact hole 218 and the plate contact hole 219, namely, unnecessary portions of the second titanium nitride film 220 and the tungsten film 221 disposed on the third interlayer insulating film 217, are removed by polishing by the CMP. Thus, a bit line contact 222 made of the second titanium nitride film 220 and the tungsten film 221 and connected to the plug 207B is formed within the bit line contact hole 218. Also, a plate contact 223 made of the second titanium nitride film 220 and the tungsten film 221 and connected to the impurity diffusion layer 205 and the first titanium nitride film 216 corresponding to the upper electrode is formed within the plate contact hole 219. Thereafter, interconnect layers 224 respectively connected to the bit line contact 222 and the plate contact 223 are formed on the third interlayer insulating film 217. In this manner, the DRAM memory cell is completed.

In this manner, in the DRAM memory cell of this embodiment, the contact connected to the first titanium nitride film 216 corresponding to the capacitor upper electrode (namely, the plate contact 223) is connected to the N-type impurity diffusion layer 205, namely, the semiconductor substrate 200.

In this embodiment, the capacitor includes the lower electrode made of the second polysilicon film 211 and the HSG film 213, the capacitor dielectric film made of the tantalum oxide film 215 and the upper electrode made of the first titanium nitride film 216.

In the semiconductor device of this embodiment, the first titanium nitride film 216 corresponding to the capacitor upper electrode is connected to the N-type impurity diffusion layer 205 and the semiconductor substrate 200 through the plate contact 223. In other words, the capacitor upper electrode is electrically connected to the semiconductor substrate 200 even during the fabrication of the semiconductor device. Therefore, charge stored in the upper electrode (i.e., the first titanium nitride film 216) by plasma used in the processes such as the etching for forming the contact holes and the deposition of the second titanium nitride film 220 flows to the semiconductor substrate 200 through the plate contact 223. In other words, the charge can be prevented from flowing to the semiconductor substrate 200 through the capacitor dielectric film (i.e., the tantalum oxide film 215) in the same manner as in Embodiment 1. Accordingly, process damage of the capacitor dielectric film can be reduced, and hence, the degradation of the capacitor dielectric film can be suppressed for preventing increase of a capacitor leakage current. Specifically, the degradation of the characteristics such as the charge holding property and the reliability of the capacitor can be prevented.

In this embodiment, a voltage applied to the upper electrode is always a positive voltage and a voltage applied to the semiconductor substrate 200 is always 0 or a negative voltage. Therefore, PN junction formed between the N-type impurity diffusion layer 205 and the semiconductor substrate 200 that is doped with the P-type impurity for controlling the threshold voltage of the DRAM cell transistor is always placed in a negative bias state. Accordingly, an excessively large current never flows to the impurity diffusion layer 205 and the first titanium nitride film 216 corresponding to the upper electrode.

Also, in this embodiment, the bit line contact hole 218 and the plate contact hole 219 are formed by using the same resist pattern. Instead, the following method may be employed: After forming the bit line contact hole 218, a photoresist film having an opening in the plate contact region alone is formed by the lithography, and then, the third interlayer insulating film 217 and the like are successively etched by using the photoresist film as a mask, thereby forming the plate contact hole 219. Alternatively, after forming the plate contact hole 219, the bit line contact hole 218 may be formed by using a resist pattern having an opening in the bit line contact region alone.

### Embodiment 3

Now, a semiconductor device and a fabrication method for the semiconductor device according to Embodiment 3 of the invention will be described.

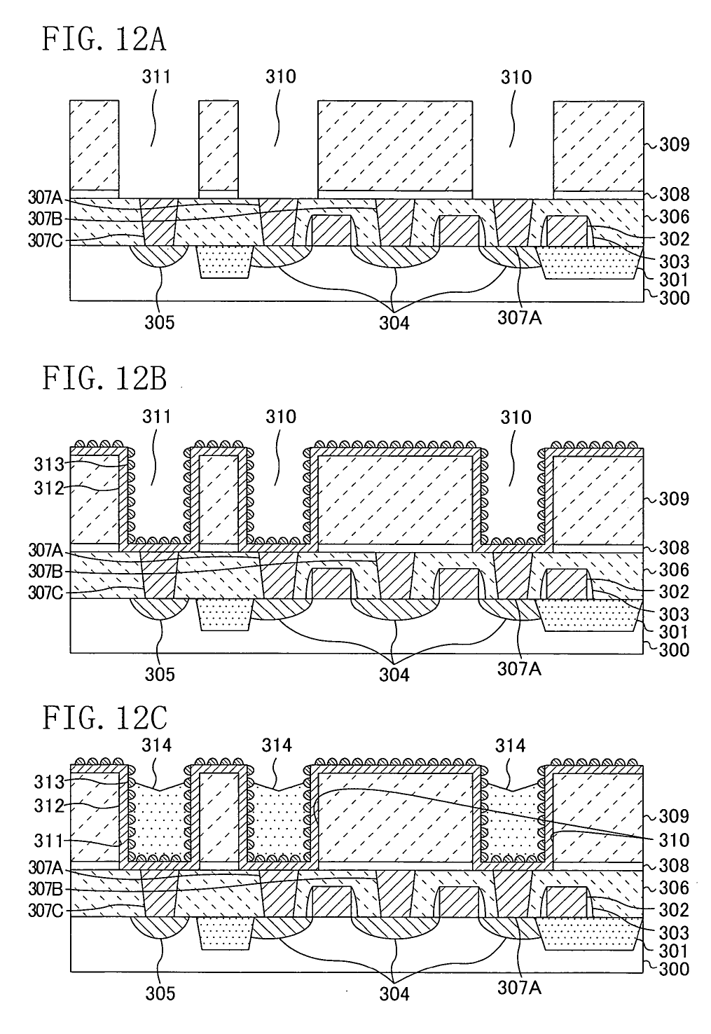

FIGS. 12A through 12C, 13A through 13C, 14A, 14B and 15A through 15C are cross-sectional views for showing procedures in the method for fabricating the semiconductor device of Embodiment 3.

First, as shown in FIG. 12A, after forming a shallow trench isolation region 301 in a semiconductor substrate 300 of, for example, silicon, a p-type impurity such as boron (B) is implanted into the semiconductor substrate 300 at energy of 15 keV and a dose of approximately 8×10¹²/cm² for controlling a threshold voltage of a DRAM cell transistor. Next, a gate insulating film (not shown) with a thickness of, for example, 7.5 nm and a first polysilicon film with a thickness of, for example, 200 nm are successively deposited on the semiconductor substrate 300, and then, the first polysilicon film is patterned by the lithography and the dry etching, thereby forming a gate electrode 302. Then, after forming a resist film (not shown) having an opening in a memory cell region alone by the lithography, an n-type impurity such as phosphorus (P) is implanted into the semiconductor substrate 300 by the ion implantation at energy of 10 keV and a dose of approximately 2×10¹³/cm² by using the resist film and the gate electrode 302 as a mask. Thus, LDD regions 304 corresponding to source/drain regions (of N-type) of the memory cell transistor and an N-type impurity diffusion layer 305 are formed. It is noted that the shallow trench isolation region 301 is present between the LDD region 304 and the impurity diffusion layer 305.

Thereafter, an insulating film such as a TEOS film is deposited over the whole semiconductor substrate 300 by the CVD, and the insulating film is etched by the anisotropic dry etching, thereby forming an insulating sidewall 303 on the side face of the gate electrode 302. Next, a first interlayer insulating film 306 with a thickness of approximately 800 nm of, for example, an NSG film is formed over the whole semiconductor substrate 300 by the CVD. Then, the first interlayer insulating film 306 is polished by a thickness of approximately 200 nm by the CMP so as to planarize the surface of the first interlayer insulating film 306.

Next, a plurality of contact holes reaching the LDD regions 304 of the DRAM cell transistor and a contact hole reaching the N-type impurity diffusion layer 305 are formed in the first interlayer insulating film 306 by the lithography and the dry etching. Then, a plug 307A to be connected to a capacitor lower electrode or a plug 307B to be connected to an interconnect (bit line) is formed within each contact hole reaching the LDD region 304, and a plug 307C to be connected to a capacitor upper electrode is formed within the contact hole reaching the impurity diffusion layer 305. The plugs 307A through 307C are specifically formed as follows: First, native oxide formed on the LDD regions 304 and the impurity diffusion layer 305 exposed on the bottoms of the contact holes is removed by the wet etching using a cleaning fluid including hydrofluoric acid. Then, a low-resistance polysilicon film doped with an n-type impurity such as P (phosphorus) is deposited by the CVD on the first interlayer insulating film 306 including the insides of the contact holes. Subsequently, a portion of the polysilicon film deposited outside the contact holes is removed by polishing through the CMP, thereby forming the plugs 307A through 307C.

Next, a silicon nitride film 308 with a thickness of, for example, 50 nm and a second interlayer insulating film 309 with a thickness of approximately 700 nm of, for example, a BPSG film are successively deposited on the first interlayer insulating film 306 including the plugs 307A through 307C. Then, after forming a photoresist film (not shown) having openings in a capacitor region and a dummy capacitor region on the second interlayer insulating film 309 by the lithography, the second interlayer insulating film 309 and the silicon nitride film 308 are successively etched by the dry etching by using the photoresist film as a mask, thereby forming a recess 310 for forming a capacitor and a recess 311 for forming a dummy capacitor. At this point, the top face of the plug 307A is exposed on the bottom of the recess 310 and the top face of the plug 307C is exposed on the bottom of the recess 311.

Next, after removing native oxide formed on the plug 307A exposed within the recess 310 and the plug 307C exposed within the recess 311 by the wet etching using a cleaning fluid including hydrofluoric acid, a second polysilicon film 312 doped with an n-type impurity such as P (phosphorus) is deposited by the CVD on the second interlayer insulating film 309 including the recesses 310 and 311 as shown in FIG. 12B. Then, an amorphous silicon film with a thickness of, for example, approximately 25 nm is deposited on the second polysilicon film 312. Next, after removing native oxide formed on the amorphous silicon film by using a cleaning fluid including hydrofluoric acid, the semiconductor substrate 300 is subjected to annealing while supplying monosilane (SiH₄) onto the surface of the amorphous silicon film in a reduced pressure atmosphere, thereby polycrystallizing the amorphous silicon film and growing silicon grains thereon. Thus, an HSG film 313 is formed on the second polysilicon film 312. Subsequently, the semiconductor substrate 300 is subjected to annealing at a temperature of, for example, 700° C. for 6 minutes in a gas atmosphere including PH₃, thereby doping the HSG film 313 with P. In this embodiment, this HSG film 313 doped with P is used as a lower electrode of a MIS capacitor of the DRAM.

Next, as shown in FIG. 12C, after applying a resist film on the HSG film 313, the whole resist film is subjected to the exposure and the development by the lithography thereby allowing a resist film 314 to selectively remain merely within the recess 310 corresponding to the capacitor region and the recess 311 corresponding to the dummy capacitor region.

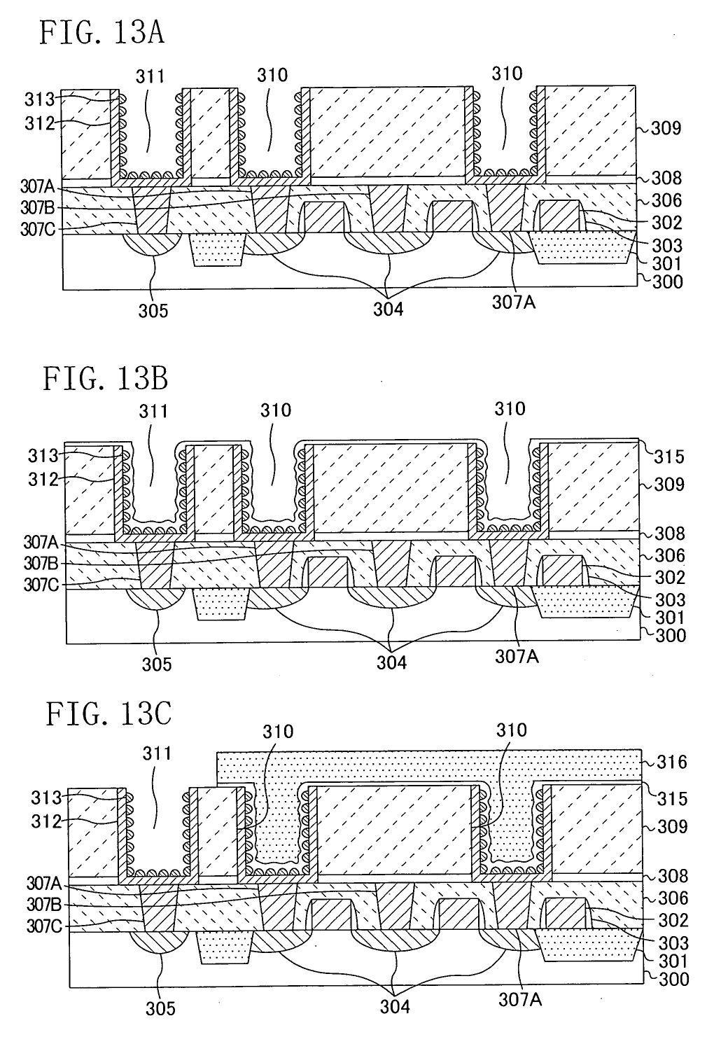

Next, after the HSG film 313 and the second polysilicon film 312 are subjected to the anisotropic etching by the dry etching with the resist film 314 used as a mask, the resist film 314 is removed by the ashing using the dry etching and the wet etching. Thus, as shown in FIG. 13A, the HSG film 313 and the second polysilicon film 312 corresponding to the lower electrode and a dummy lower electrode can remain merely within the recess 310 corresponding to the capacitor region and the recess 311 corresponding to the dummy capacitor region. At this point, the second polysilicon film 312 used as the lower electrode and remaining within the recess 310 is connected to the plug 307A, and the second polysilicon film 312 used as the dummy lower electrode and remaining within the recess 311 is connected to the plug 307C.

Next, after removing native oxide formed on the HSG film 313 by the wet etching using a cleaning fluid including hydrofluoric acid, the HSG film 313 is exposed to plasma of a nitrogen gas, thereby forming a nitride film (not shown) with a thickness of approximately 2 nm on the HSG film 313. This nitride film functions as an anti-oxidation film for the HSG film 313 in crystallization and reforming process of a tantalum oxide film performed in an oxidizing atmosphere described below.

Next, as shown in FIG. 13B, a tantalum oxide film 315 is deposited over the substrate, and the tantalum oxide film 315 is annealed at a temperature of, for example, 800° C. for 60 seconds in an oxygen atmosphere, thereby polycrystallizing the tantalum oxide film 315.

Next, as shown in FIG. 13C, a resist film 316 covering the capacitor region (namely, the recess 310) and having an opening in the dummy capacitor region (namely, the recess 311) is formed by the lithography, and the tantalum oxide film 315 is etched by the dry etching by using the resist film 316 as a mask, and thereafter, the resist film 316 is removed by the ashing using the dry etching and the wet etching. Thus, a portion of the tantalum oxide film 315 remaining within the recess 311 corresponding to the dummy capacitor region can be removed, thereby exposing the HSG film 313 within the recess 311.

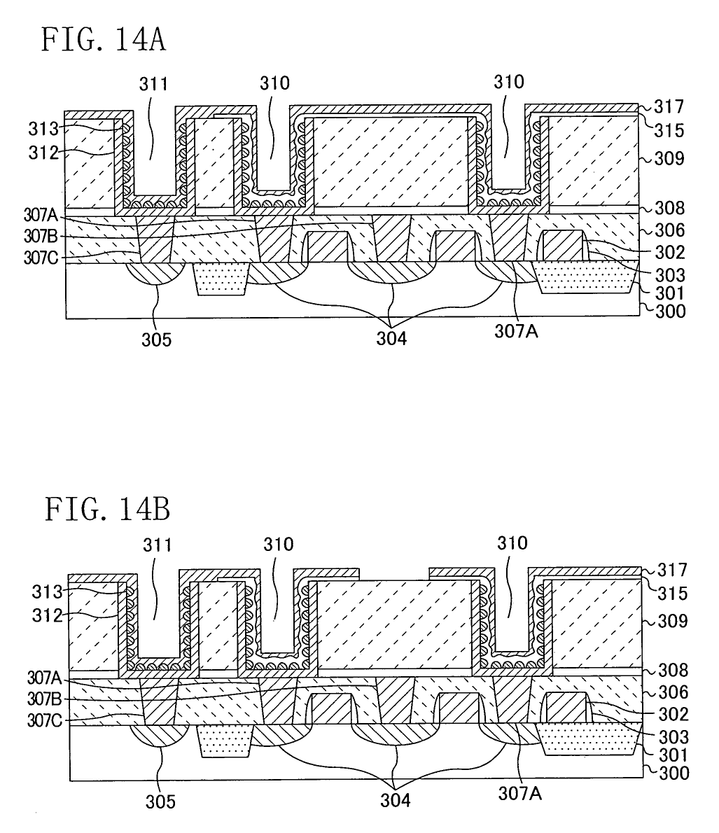

Subsequently, as shown in FIG. 14A, a first titanium nitride film 317 is deposited on the tantalum oxide film 315 including the recess 310 and the HSG film 313 within the recess 311 by the CVD using titanium chloride (TiCl₄) and ammonia (NH₃) as material gasses. In this embodiment, the first titanium nitride film 317 is used as an upper electrode of the capacitor of the DRAM.

Next, as shown in FIG. 14B, the tantalum oxide film 315 and the first titanium nitride film 317 are patterned by the lithography and the dry etching, thereby forming a capacitor dielectric film and the upper electrode on the lower electrode (namely, the HSG film 313 and the second polysilicon film 312 within the recess 310), and thus, the capacitor is completed. At this point, a dummy capacitor including the dummy lower electrode (made of the HSG film 313 and the second polysilicon film 312) and the upper electrode (made of the first titanium nitride film 317) is formed within the recess 311. It is noted that the first titanium nitride film 317 corresponding to the upper electrode extends, for plate contact, over the second interlayer insulating film 309 provided in the vicinity of the recess 310 corresponding to the capacitor region and the recess 311 corresponding to the dummy capacitor region.

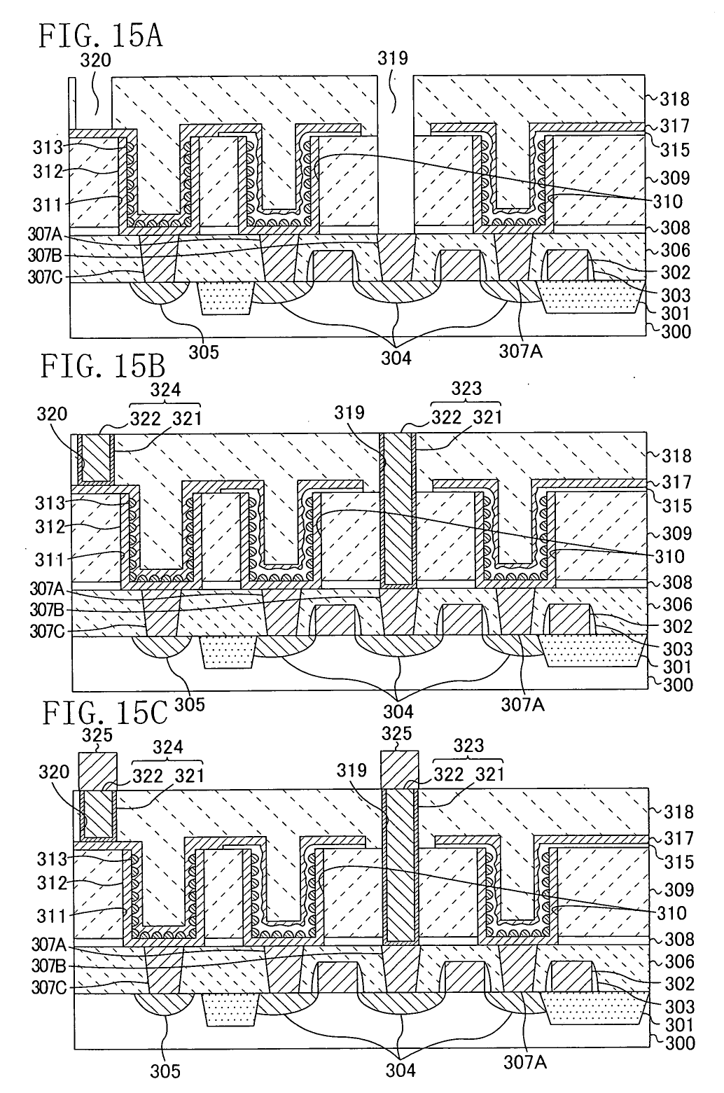

Thereafter, as shown in FIG. 15A, a third interlayer insulating film 318 with a thickness of, for example, approximately 800 nm is deposited on the second interlayer insulating film 309 including the first titanium nitride film 317 corresponding to the upper electrode, and the surface of the third interlayer insulating film 318 is planarized by polishing it by a thickness of approximately 300 nm by the CMP. Then, after a photoresist film (not shown) having openings in a bit line contact region and a plate contact region alone is formed on the third interlayer insulating film 318 by the lithography, the third interlayer insulating film 318, the second interlayer insulating film 309 and the silicon nitride film 308 are successively etched by the dry etching by using the photoresist film as a mask, thereby forming a bit line contact hole 319 reaching the plug 307B. Simultaneously, in the plate contact region, the third interlayer insulating film 318 is etched, thereby forming a plate contact hole 320 reaching the first titanium nitride film 317 corresponding to the upper electrode.

Next, as shown in FIG. 15B, a second titanium nitride film 321 working as an adhesion layer is deposited by the CVD at a wafer temperature of 700° C. on the third interlayer insulating film 318 and within the bit line contact hole 319 and the plate contact hole 320. Then, a tungsten film 322 is deposited by the CVD on the second titanium nitride film 321 so as to completely fill the bit line contact hole 319 and the plate contact hole 320. Next, portions of the second titanium nitride film 321 and the tungsten film 322 deposited outside the bit line contact hole 319 and the plate contact hole 320, namely, unnecessary portions of the second titanium nitride film 321 and the tungsten film 322 disposed on the third interlayer insulating film 318, are removed by polishing by the CMP. Thus, a bit line contact 323 made of the second titanium nitride film 321 and the tungsten film 322 and connected to the plug 307B is formed within the bit line contact hole 319. Also, a plate contact 324 made of the second titanium nitride film 321 and the tungsten film 322 and connected to the first titanium nitride film 317 corresponding to the upper electrode is formed within the plate contact hole 320.

Thereafter, as shown in FIG. 15C, interconnect layers 325 respectively connected to the bit line contact 323 and the plate contact 324 are formed on the third interlayer insulating film 318. In this manner, the DRAM memory cell is completed.

In this manner, in the DRAM memory cell of this embodiment, the dummy lower electrode connected to the first titanium nitride film 317 corresponding to the capacitor upper electrode is connected to the N-type impurity diffusion layer 305, namely, the semiconductor substrate 300, through the plug 307C.

In this embodiment, the capacitor includes the lower electrode made of the second polysilicon film 312 and the HSG film 313, the capacitor dielectric film made of the tantalum oxide film 315 and the upper electrode made of the first titanium nitride film 317.

In the semiconductor device of this embodiment, the first titanium nitride film 317 corresponding to the capacitor upper electrode is electrically connected to the dummy lower electrode (i.e., the HSG film 313 and the second polysilicon film 312) within the recess 311 corresponding to the dummy capacitor region and the dummy lower electrode is electrically connected to the N-type impurity diffusion layer 305 through the plug 307C. In other words, the capacitor upper electrode is electrically connected to the semiconductor substrate 300 even during the fabrication of the semiconductor device. Therefore, charge stored in the upper electrode (i.e., the first titanium nitride film 317) by the plasma used in the processes such as the etching for forming the contact holes and the deposition of the second titanium nitride film 321 flows to the semiconductor substrate 300 through the dummy lower electrode and the plug 307C. In other words, the charge can be prevented from flowing to the semiconductor substrate 300 through the capacitor dielectric film (i.e., the tantalum oxide film 315) in the same manner as in Embodiments 1 and 2. Accordingly, the process damage of the capacitor dielectric film can be reduced, and hence, the degradation of the capacitor dielectric film can be suppressed for preventing increase of a capacitor leakage current. Specifically, the degradation of the characteristics such as the charge holding property and the reliability of the capacitor can be prevented.

In this embodiment, a voltage applied to the upper electrode is always a positive voltage and a voltage applied to the semiconductor substrate 300 is always 0 or a negative voltage. Therefore, PN junction formed between the N-type impurity diffusion layer 305 and the semiconductor substrate 300 that is doped with the P-type impurity for controlling the threshold voltage of the DRAM cell transistor is always placed in a negative bias state. Accordingly, an excessively large current never flows to the impurity diffusion layer 305 and the first titanium nitride film 317 corresponding to the upper electrode.

Also, in this embodiment, the bit line contact hole 319 and the plate contact hole 320 are formed by using the same resist pattern. Instead, the following method may be employed: After forming the bit line contact hole 319, a photoresist film having an opening in the plate contact region alone is formed by the lithography, and then, the third interlayer insulating film 318 is etched with the photoresist film used as a mask, thereby forming the plate contact hole 320. Alternatively, after forming the plate contact hole 320, the bit line contact hole 319 may be formed by using a resist pattern having an opening in the bit line contact region alone.

### Embodiment 4

Now, a semiconductor device and a fabrication method for the semiconductor device according to Embodiment 4 of the invention will be described.

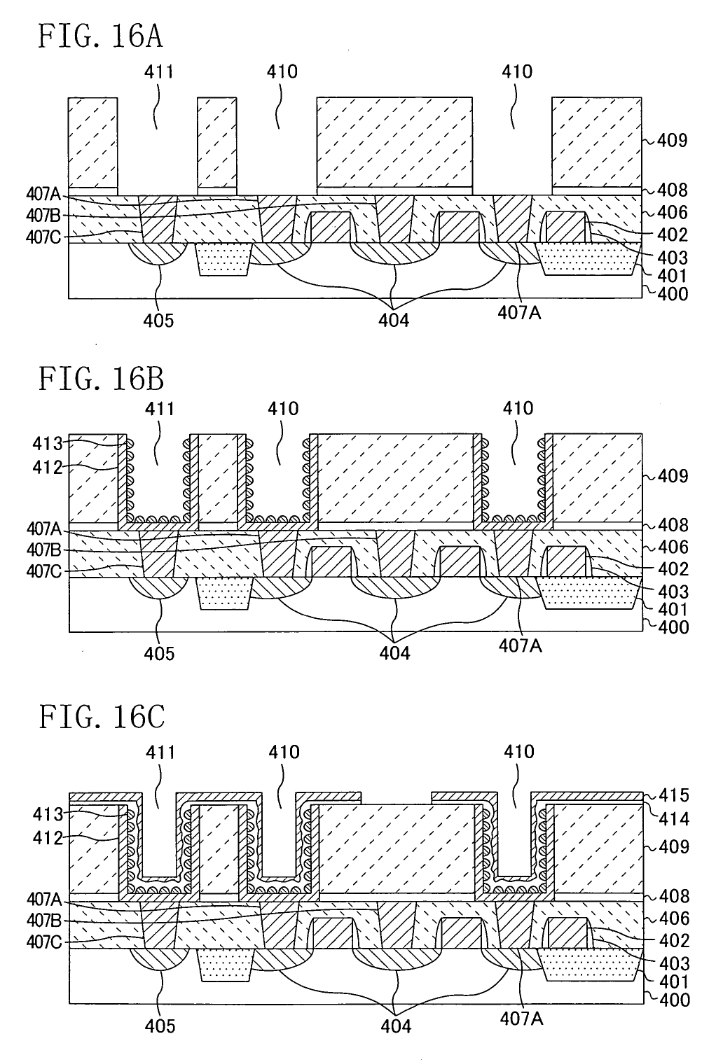

FIGS. 16A through 16C, 17A, 17B, 18A and 18B are cross-sectional views for showing procedures in the method for fabricating the semiconductor device of Embodiment 4.

First, as shown in FIG. 16A, after forming a shallow trench isolation region 401 in a semiconductor substrate 400 of, for example, silicon, a p-type impurity such as boron (B) is implanted into the semiconductor substrate 400 at energy of 15 keV and a dose of approximately 8×10¹²/cm² for controlling a threshold voltage of a DRAM cell transistor. Next, a gate insulating film (not shown) with a thickness of, for example, 7.5 nm and a first polysilicon film with a thickness of, for example, 200 nm are successively deposited on the semiconductor substrate 400, and then, the first polysilicon film is patterned by the lithography and the dry etching, thereby forming a gate electrode 402. Then, after forming a resist film (not shown) having an opening in a memory cell region alone by the lithography, an n-type impurity such as phosphorus (P) is implanted into the semiconductor substrate 400 by the ion implantation at energy of 10 keV and a dose of approximately 2×10¹³/cm² by using the resist film and the gate electrode 402 as a mask. Thus, LDD regions 404 corresponding to source/drain regions (of N-type) of the memory cell transistor and an N-type impurity diffusion layer 405 are formed. It is noted that the shallow trench isolation region 401 is present between the LDD region 404 and the impurity diffusion layer 405.

Thereafter, an insulating film such as a TEOS film is deposited over the whole semiconductor substrate 400 by the CVD, and the insulating film is etched by the anisotropic dry etching, thereby forming an insulating sidewall 403 on the side face of the gate electrode 402. Next, a first interlayer insulating film 406 with a thickness of approximately 800 nm of, for example, an NSG film is formed over the whole semiconductor substrate 400 by the CVD. Then, the first interlayer insulating film 406 is polished by a thickness of approximately 200 nm by the CMP so as to planarize the surface of the first interlayer insulating film 406.

Next, a plurality of contact holes reaching the LDD regions 404 of the DRAM cell transistor and a contact hole reaching the N-type impurity diffusion layer 405 are formed in the first interlayer insulating film 406 by the lithography and the dry etching. Then, a plug 407A to be connected to a capacitor lower electrode or a plug 407B to be connected to an interconnect (bit line) is formed within each contact hole reaching the LDD region 404, and a plug 407C to be connected to a capacitor upper electrode is formed within the contact hole reaching the impurity diffusion layer 405. The plugs 407A through 407C are specifically formed as follows: First, native oxide formed on the LDD regions 404 and the impurity diffusion layer 405 exposed on the bottoms of the contact holes is removed by the wet etching using a cleaning fluid including hydrofluoric acid. Then, a low-resistance polysilicon film doped with an n-type impurity such as P (phosphorus) is deposited by the CVD on the first interlayer insulating film 406 including the insides of the contact holes. Subsequently, a portion of the polysilicon film deposited outside the contact holes is removed by polishing through the CMP, thereby forming the plugs 407A through 407C.

Next, a silicon nitride film 408 with a thickness of, for example, 50 nm and a second interlayer insulating film 409 with a thickness of approximately 700 nm of, for example, a BPSG film are successively deposited by the CVD on the first interlayer insulating film 406 including the plugs 407A through 407C. Then, after forming a photoresist film (not shown) having openings in a capacitor region and a dummy capacitor region on the second interlayer insulating film 409 by the lithography, the second interlayer insulating film 409 and the silicon nitride film 408 are successively etched by the dry etching by using the photoresist film as a mask, thereby forming a recess 410 for forming a capacitor and a recess 411 for forming a dummy capacitor. At this point, the top face of the plug 407A is exposed on the bottom of the recess 410 and the top face of the plug 407C formed on the N-type impurity diffusion layer 405 is exposed on the bottom of the recess 411.

Next, after removing native oxide formed on the plug 407A exposed within the recess 410 and the plug 407C exposed within the recess 411 by the wet etching using a cleaning fluid including hydrofluoric acid, a second polysilicon film 412 doped with an n-type impurity such as P (phosphorus) is deposited by the CVD on the second interlayer insulating film 409 including the recesses 410 and 411 as shown in FIG. 16B. Then, an amorphous silicon film with a thickness of, for example, approximately 25 nm is deposited on the second polysilicon film 412. Next, after removing native oxide formed on the amorphous silicon film by using a cleaning fluid including hydrofluoric acid, the semiconductor substrate 400 is subjected to annealing while supplying monosilane (SiH₄) onto the surface of the amorphous silicon film in a reduced pressure atmosphere, thereby polycrystallizing the amorphous silicon film and growing silicon grains thereon. Thus, an HSG film 413 is formed on the second polysilicon film 412. Subsequently, the semiconductor substrate 400 is subjected to annealing at a temperature of, for example, 700° C. for 6 minutes in a gas atmosphere including PH₃, thereby doping the HSG film 413 with P. In this embodiment, this HSG film 413 doped with P is used as a lower electrode of a MIS capacitor of the DRAM.

Next, after applying a resist film on the HSG film 413, the whole resist film is subjected to the exposure and the development by the lithography, thereby allowing a resist film (not shown) to selectively remain merely within the recess 410 corresponding to the capacitor region and the recess 411 corresponding to the dummy capacitor region. Subsequently, after the HSG film 413 and the second polysilicon film 412 are subjected to the anisotropic etching by the dry etching with the resist film used as a mask, the resist film is removed by the ashing using the dry etching and the wet etching. Thus, as shown in FIG. 16B, the HSG film 413 and the second polysilicon film 412 corresponding to the lower electrode and a dummy lower electrode can remain merely within the recess 410 corresponding to the capacitor region and the recess 411 corresponding to the dummy capacitor region. At this point, the second polysilicon film 412 used as the lower electrode and remaining within the recess 410 is connected to the plug 407A, and the second polysilicon film 412 used as the dummy lower electrode and remaining within the recess 411 is connected to the plug 407C.

Next, after removing native oxide formed on the HSG film 413 by the wet etching using a cleaning fluid including hydrofluoric acid, the HSG film 413 is exposed to plasma of a nitrogen gas, thereby forming a nitride film (not shown) with a thickness of approximately 2 nm on the HSG film 413. This nitride film functions as an anti-oxidation film for the HSG film 413 in crystallization and reforming process of a tantalum oxide film performed in an oxidizing atmosphere described below.

Next, as shown in FIG. 16C, a tantalum oxide film 414 is deposited over the substrate, and the tantalum oxide film 414 is annealed at a temperature of, for example, 800° C. for 60 seconds in an oxygen atmosphere, thereby polycrystallizing the tantalum oxide film 414. Subsequently, a first titanium nitride film 415 is deposited on the tantalum oxide film 414 including the recesses 410 and 411 by the CVD using titanium chloride (TiCl₄) and ammonia (NH₃) as material gasses. In this embodiment, the first titanium nitride film 415 is used as an upper electrode of the capacitor of the DRAM. Next, the tantalum oxide film 414 and the first titanium nitride film 415 are patterned by the lithography and the dry etching, thereby forming a capacitor dielectric film and the upper electrode on the lower electrode (namely, the HSG film 413 and the second polysilicon film 412 disposed within the recess 410), and thus, the capacitor is completed. At this point, a dummy capacitor including the dummy lower electrode (made of the HSG film 413 and the second polysilicon film 412), a capacitor dielectric film (made of the tantalum oxide film 414) and the upper electrode (made of the first titanium nitride film 415) is formed within the recess 411. It is noted that the first titanium nitride film 415 corresponding to the upper electrode extends, for plate contact, over the second interlayer insulating film 409 provided in the vicinity of the recess 410 corresponding to the capacitor region and the recess 411 corresponding to the dummy capacitor region.

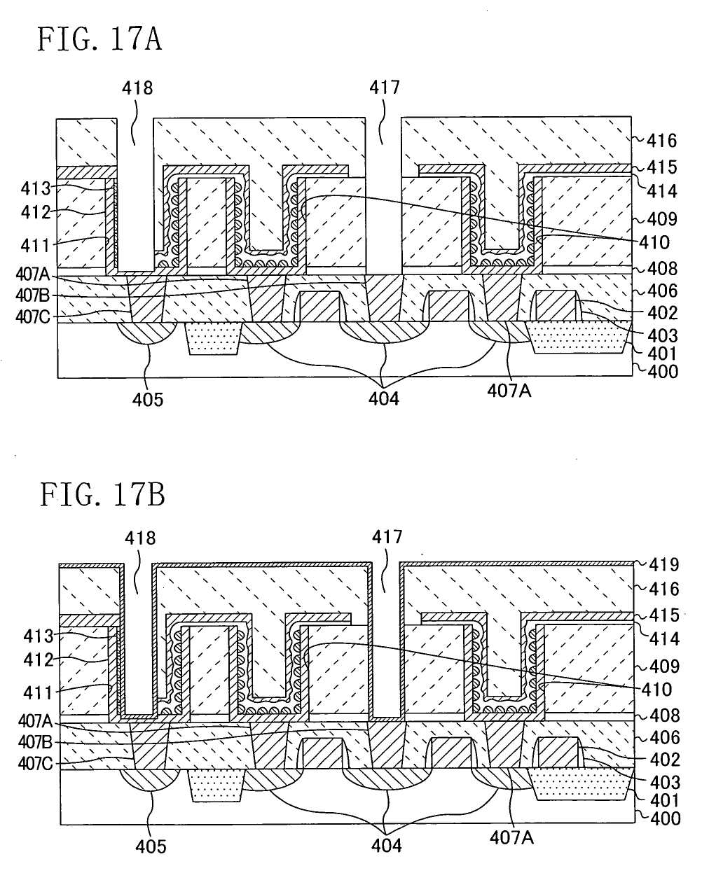

Thereafter, as shown in FIG. 17A, a third interlayer insulating film 416 with a thickness of, for example, approximately 800 nm is deposited on the second interlayer insulating film 409 including the first titanium nitride film 415 corresponding to the upper electrode, and the surface of the third interlayer insulating film 416 is planarized by polishing it by a thickness of approximately 300 nm by the CMP. Then, a photoresist film (not shown) having openings in a bit line contact region and a plate contact region alone is formed on the third interlayer insulating film 416 by the lithography. At this point, at least a part of the opening of the photoresist film corresponding to the plate contact region is set to be positioned on the dummy lower electrode (i.e., the HSG film 413 and the second polysilicon film 412) within the recess 411 corresponding to the dummy capacitor region. Thereafter, the third interlayer insulating film 416, the second interlayer insulating film 409 and the silicon nitride film 408 are successively etched by the dry etching by using the photoresist film as a mask, thereby forming a bit line contact hole 417 reaching the plug 407B. Simultaneously, in the plate contact region, the third interlayer insulating film 416 and the first titanium nitride film 415 and the tantalum oxide film 414 included in the dummy capacitor are etched, thereby forming a plate contact hole 418 reaching the dummy lower electrode (i.e., the HSG film 413 and the second polysilicon film 412).

Next, as shown in FIG. 17B, a second titanium nitride film 419 working as an adhesion layer is deposited by the CVD at a wafer temperature of 700° C. on the third interlayer insulating film 416 and within the bit line contact hole 417 and the plate contact hole 418. At this point, the second titanium nitride film 419 formed within the plate contact hole 418 is in contact with the first titanium nitride film 415 corresponding to the upper electrode and also in contact with the HSG film 413 or the second polysilicon film 412 formed within the recess 411 corresponding to the dummy capacitor region.

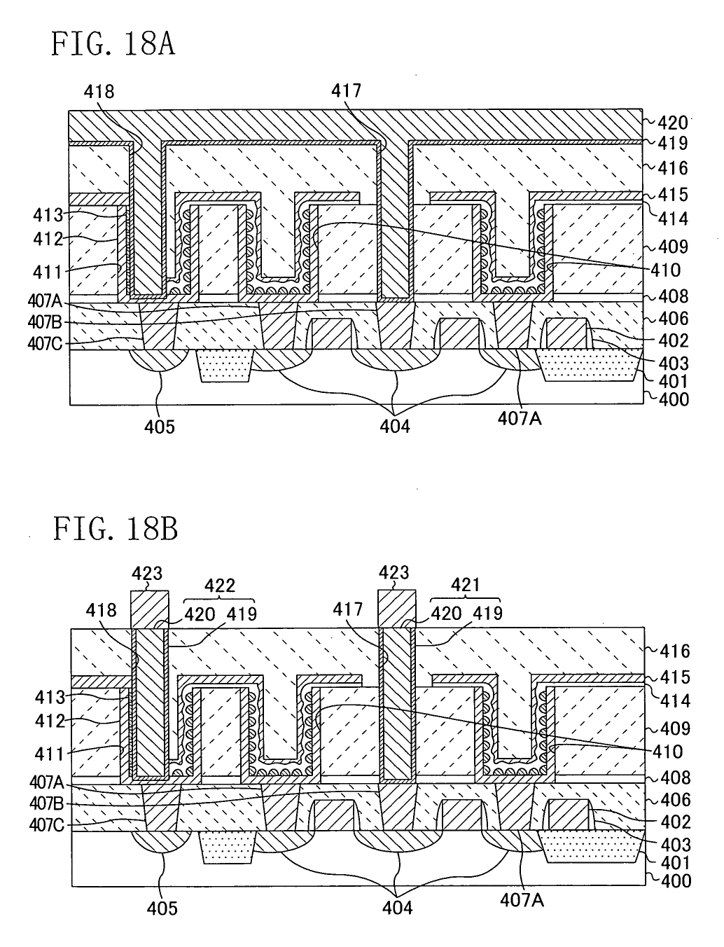

Then, as shown in FIG. 18A, a tungsten film 420 is deposited by the CVD on the second titanium nitride film 419 so as to completely fill the bit line contact hole 417 and the plate contact hole 418. Next, portions of the second titanium nitride film 419 and the tungsten film 420 deposited outside the bit line contact hole 417 and the plate contact hole 418, namely, unnecessary portions of the second titanium nitride film 419 and the tungsten film 420 disposed on the third interlayer insulating film 416, are removed by polishing by the CMP. Thus, a bit line contact 421 made of the second titanium nitride film 419 and the tungsten film 420 and connected to the plug 407B is formed within the bit line contact hole 417. Also, a plate contact 422 made of the second titanium nitride film 419 and the tungsten film 420 and connected to the first titanium nitride film 415 corresponding to the upper electrode and the HSG film 413 or the second polysilicon film 412 corresponding to the dummy lower electrode is formed within the plate contact hole 418.

Thereafter, as shown in FIG. 18B, interconnect layers 423 respectively connected to the bit line contact 421 and the plate contact 422 are formed on the third interlayer insulating film 416. In this manner, the DRAM memory cell is completed.

In this manner, in the DRAM memory cell of this embodiment, the plate contact 422 connected to the first titanium nitride film 415 corresponding to the capacitor upper electrode is connected to the N-type impurity diffusion layer 405, namely, the semiconductor substrate 400, through the dummy lower electrode (i.e., the HSG film 413 or the second polysilicon film 412) and the plug 407C.

In this embodiment, the capacitor includes the lower electrode made of the second polysilicon film 412 and the HSG film 413, the capacitor dielectric film made of the tantalum oxide film 414 and the upper electrode made of the first titanium nitride film 415.

In the semiconductor device of this embodiment, the plate contact 422 connected to the first titanium nitride film 415 corresponding to the capacitor upper electrode is electrically connected to the dummy lower electrode (i.e., the HSG film 413 and the second polysilicon film 412) within the recess 411 corresponding to the dummy capacitor region and the dummy lower electrode is electrically connected to the N-type impurity diffusion layer 405 through the plug 407C. In other words, the capacitor upper electrode is electrically connected to the semiconductor substrate 400 even during the fabrication of the semiconductor device. Therefore, charge stored in the upper electrode (i.e., the first titanium nitride film 415) by plasma used in the processes such as the etching for forming the contact holes and the deposition of the second titanium nitride film 419 flows to the semiconductor substrate 400 through the plate contact 422, the dummy lower electrode and the plug 407C. In other words, the charge can be prevented from flowing to the semiconductor substrate 400 through the capacitor dielectric film (i.e., the tantalum oxide film 414) in the same manner as in Embodiments 1 through 3. Accordingly, the process damage of the capacitor dielectric film can be reduced, and hence, the degradation of the capacitor dielectric film can be suppressed for preventing increase of a capacitor leakage current. Specifically, the degradation of the characteristics such as the charge holding property and the reliability of the capacitor can be prevented.

In this embodiment, a voltage applied to the upper electrode is always a positive voltage and a voltage applied to the semiconductor substrate 400 is always 0 or a negative voltage. Therefore, PN junction formed between the N-type impurity diffusion layer 405 and the semiconductor substrate 400 that is doped with the P-type impurity for controlling the threshold voltage of the DRAM cell transistor is always placed in a negative bias state. Accordingly, an excessively large current never flows to the impurity diffusion layer 405 and the first titanium nitride film 415 corresponding to the upper electrode.

Also, in this embodiment, the bit line contact hole 417 and the plate contact hole 418 are formed by using the same resist pattern. Instead, the following method may be employed: After forming the bit line contact hole 417, a photoresist film having an opening merely in the plate contact region (at least a part of which overlaps the dummy capacitor region (namely, a region where the dummy lower electrode is formed)) is formed by the lithography, and then, the third interlayer insulating film 416 is etched with the photoresist film used as a mask, thereby forming the plate contact hole 418. Alternatively, after forming the plate contact hole 418, the bit line contact hole 417 may be formed by using a resist pattern having an opening in the bit line contact region alone.

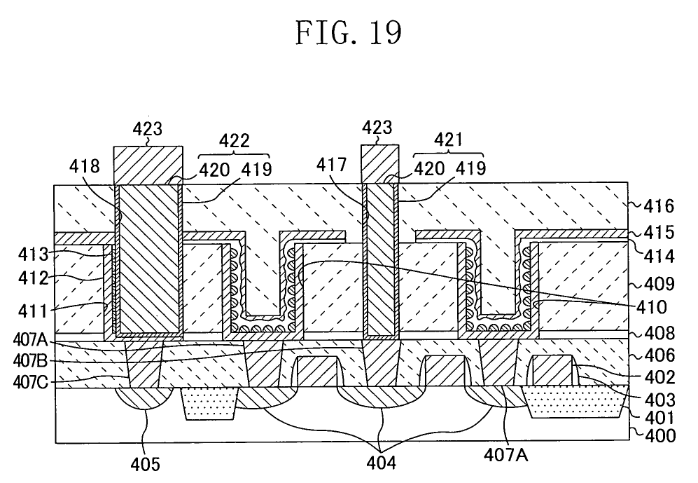

Furthermore, in this embodiment, the shape and the position of the plate contact 422 are not particularly specified as far as the plate contact 422 penetrates the first titanium nitride film 415 (corresponding to the upper electrode) and the tantalum oxide film 414 (corresponding to the capacitor dielectric film) and is in contact with the dummy lower electrode (i.e., the HSG film 413 or the second polysilicon film 412 formed within the recess 411). For example, as shown in FIG. 19 (which is a cross-sectional view of a semiconductor device according to a modification of Embodiment 4), a plate contact 422 having a larger dimension than the bit line contact 421 may be formed on the recess 411 corresponding to the dummy capacitor region. In this case, the contact area between the plate contact 422 and the dummy lower electrode (i.e., the HSG film 413 or the second polysilicon film 412 formed within the recess 411) can be sufficiently secured. Alternatively, although not shown in a drawing, a plate contact 422 in contact with the dummy lower electrode (i.e., the HSG film 413 or the second polysilicon film 412) in an upper portion of the recess 411 may be formed by etching portions of the third interlayer insulating film 416, the first titanium nitride film 415 and the tantalum oxide film 414 present outside the recess 411. In this case, the plate contact 422 may be in contact with the dummy lower electrode on one side or both sides of the inner wall of the recess 411.

Moreover, the plate contact 422 may penetrate the HSG film 413 to be in contact with the second polysilicon film 412 within the dummy lower electrode in this embodiment. Alternatively, it may penetrate the dummy lower electrode formed on the bottom of the recess 411 so as to be in direct contact with the plug 407C.

What is claimed is:

1. A semiconductor device comprising:
a first insulating film formed on a semiconductor substrate;
a second insulating film formed on said first insulating film and having a recess corresponding to a capacitor region;
a lower electrode formed within said recess;
a capacitor dielectric film formed on said lower electrode;
an upper electrode formed on said capacitor dielectric film; and
a conductive portion formed in said first insulating film and said second insulating film for electrically connecting said semiconductor substrate to said upper electrode.

2. The semiconductor device of claim 1, further comprising:
an impurity layer formed in a surface portion of said semiconductor substrate;
a third insulating film formed on said upper electrode and said second insulating film; and
an interconnect formed on said third insulating film,
wherein said conductive portion includes:
a first plug formed in said first insulating film and connected to said impurity layer; and
a second plug formed in said second insulating film and said third insulating film and connected to said first plug, said upper electrode and said interconnect.

3. The semiconductor device of claim 1, further comprising:
an impurity layer formed in a surface portion of said semiconductor substrate;
a third insulating film formed on said upper electrode and said second insulating film; and
an interconnect formed on said third insulating film,
wherein said conductive portion is a plug formed in said first insulating film, said second insulating film and said third insulating film and connected to said impurity layer, said upper electrode and said interconnect.

4. The semiconductor device of claim 1, further comprising:
an impurity layer formed in a surface portion of said semiconductor substrate,
wherein said conductive portion includes:
a plug formed in said first insulating film and connected to said impurity layer; and
a dummy lower electrode formed in another recess formed in said second insulating film and connected to said plug, and
said upper electrode is formed also on said dummy lower electrode without providing said capacitor dielectric film therebetween.

5. The semiconductor device of claim 1, further comprising:
an impurity layer formed in a surface portion of said semiconductor substrate;
a third insulating film formed on said upper electrode and said second insulating film; and
an interconnect formed on said third insulating film,
wherein said conductive portion includes:
a first plug formed in said first insulating film and connected to said impurity layer;
a dummy lower electrode formed in another recess formed in said second insulating film and connected to said first plug; and
a second plug formed in at least said third insulating film and connected to said dummy lower electrode, said upper electrode and said interconnect, and
said capacitor dielectric film and said upper electrode are formed also on said dummy lower electrode.

6. A method for fabricating a semiconductor device comprising the steps of:
forming an impurity layer in a surface portion of a semiconductor substrate;
forming a first insulating film on said semiconductor substrate including said impurity layer;
forming, in said first insulating film, a first plug connected to said impurity layer;
forming a second insulating film on said first insulating film including said first plug;
forming a recess corresponding to a capacitor region in said second insulating film;
forming a lower electrode in said recess;
forming a capacitor dielectric film on said lower electrode;
forming an upper electrode on said capacitor dielectric film;
forming a third insulating film on said upper electrode and said second insulating film;
forming, in said second insulating film and said third insulating film, a second plug connected to said first plug and said upper electrode; and
forming, on said third insulating film, an interconnect connected to said second plug.

7. A method for fabricating a semiconductor device comprising the steps of:
forming an impurity layer in a surface portion of a semiconductor substrate;
forming a first insulating film on said semiconductor substrate including said impurity layer;
forming a second insulating film on said first insulating film;
forming, in said second insulating film, a recess corresponding to a capacitor region;
forming a lower electrode in said recess;
forming a capacitor dielectric film on said lower electrode;
forming an upper electrode on said capacitor dielectric film;
forming a third insulating film on said upper electrode and said second insulating film;
forming, in said first insulating film, said second insulating film and said third insulating film, a plug connected to said impurity layer and said upper electrode; and
forming, on said third insulating film, an interconnect connected to said plug.

8. A method for fabricating a semiconductor device comprising the steps of:
forming an impurity layer in a surface portion of a semiconductor substrate;
forming a first insulating film on said semiconductor substrate including said impurity layer;
forming, in said first insulating film, a plug connected to said impurity layer;
forming a second insulating film on said first insulating film including said plug;
forming, in said second insulating film, a first recess corresponding to a capacitor region and a second recess reaching said plug;
forming a lower electrode in said first recess and forming, in said second recess, a dummy lower electrode connected to said plug;
forming a capacitor dielectric film on said lower electrode; and
forming an upper electrode on said capacitor dielectric film and said dummy lower electrode.

9. A method for fabricating a semiconductor device comprising the steps of:
forming an impurity layer in a surface portion of a semiconductor substrate;
forming a first insulating film on said semiconductor substrate including said impurity layer;
forming, in said first insulating film, a first plug connected to said impurity layer;
forming a second insulating film on said first insulating film including said first plug;
forming, in said second insulating film, a first recess corresponding to a capacitor region and a second recess reaching said first plug;
forming a lower electrode in said first recess and forming, in said second recess, a dummy lower electrode connected to said first plug;
forming a capacitor dielectric film on said lower electrode and said dummy lower electrode;
forming an upper electrode on said capacitor dielectric film;
forming a third insulating film on said upper electrode and said second insulating film;
forming, at least in said third insulating film, a second plug connected to said dummy lower electrode and said upper electrode; and
forming, on said third insulating film, an interconnect connected to said second plug.
